(19) United States
(12) Patent Application Publication
(10) Pub. No.: US 2007/0205423 A1
(43) Pub. Date: Sep. 6, 2007

(54) SEMICONDUCTOR DEVICE

(75) Inventors: Shunpei Yamazaki, Atsugi-shi, Kanagawa-ken (JP); Junichiro Sakata, Atsugi-shi, Kanagawa-ken (JP); Tomoya Aoyama, Atsugi-shi, Kanagawa-ken (JP); Kohei Ohshima, Atsugi-shi, Kanagawa-ken (JP); Rie Matsubara, Atsugi-shi, Kanagawa-ken (JP); Hideaki Kuwabara, Atsugi-shi, Kanagawa-ken (JP)

Correspondence Address: FISH & RICHARDSON P.C., P.O. BOX 1022, MINNEAPOLIS, MN, 55440-1022, US

(73) Assignee: SEMICONDUCTOR ENERGY LABORATORY CO., LTD., Atsugi-shi (JP)

(21) Appl. No.: 11/680,287

(22) Filed: Feb. 28, 2007

(30) Foreign Application Priority Data
Mar. 3, 2006 (JP) 2006-058759

(51) Int. Cl. H01L 27/32

(52) U.S. Cl. 257/89; 257/98; 257/E51.022; 313/504; 313/112; 428/917

(57) ABSTRACT

It is an object to provide a thin-type full-color display device with the long lifetime, inexpensively, in which desired emission luminance and desired color purity can be obtained at a low voltage. In a light-emitting device capable of full-color display, among a plurality of light-emitting elements emitting different emission colors (for example, colors of red (R), green (G), and blue (B)), at least one of the light-emitting elements of an emission color is a light-emitting element including an organic compound (an organic EL element), and the other light-emitting element of an emission color is a light-emitting element using an inorganic material as a light-emitting layer or a fluorescent layer (an inorganic EL element). It is to be noted that the organic EL element and the inorganic EL element are formed over the same substrate.

### BACKGROUND OF THE INVENTION

1. Field of the Invention

The present invention relates to a semiconductor device including a plurality of light-emitting elements and a manufacturing method thereof. For example, the present invention relates to an electronic device that mounts a light-emitting display device including a light-emitting element as a component.

It is to be noted that a semiconductor device in the present specification generally indicates a device capable of functioning by utilizing semiconductor characteristics, and electro-optic devices, semiconductor circuits, and electronic devices are all semiconductor devices.

2. Description of the Related Art

A phenomenon in which light emission is generated when applying an electric field to a substance is referred to as an EL (Electroluminescence) phenomenon, which is a known phenomenon. An inorganic EL using an inorganic thin film of ZnS:Mn and an organic EL using an organic evaporation thin film are particularly bright and exhibit EL light emission with high efficiency; therefore, application to display thereof is attempted.

Recently, in order to achieve a display capable of full-color display, various structures have been proposed. For example, structures have been examined, such as a structure for performing full-color display by combination of a white light-emitting element and a color filter and a structure for performing full-color display by arrangement of three light-emitting layers of a light-emitting layer exhibiting a red color, a light-emitting layer exhibiting a green color, and a light-emitting layer exhibiting a blue color, respectively.

An organic light-emitting device constituted by a pixel group having pixels of four colors of red, green, blue, and white are disclosed in Patent Document 1: a specification of U.S. patent application No. 2002/0186214.

In addition, the present applicant discloses a full-color display device in which at least one of EL elements has a triplet compound and the other EL element has a singlet compound in a light-emitting device that has a plurality of EL elements emitting light of different colors in Patent Document 2: Japanese Published Patent Application No. 2002-62824.

### SUMMARY OF THE INVENTION

Although emission luminance in an EL element is controlled by a voltage that is applied to the EL element, a light-emitting material to be used is different depending on an emission color of the EL element. Therefore, emission luminance to the voltage becomes different.

In a case where full-color display is tried to be performed using organic EL elements each emitting light of a red color, a green color, or a blue color, light-emitting materials to be used are different in each EL element. Therefore, it is difficult to achieve a long operating life of the EL element on a condition that light-emitting elements of a red color, a green color, or a blue color all have the same luminance and be driven at a low voltage.

It is an object of the present invention to provide a thin-type full-color display device with the long lifetime, inexpensively, in which desired emission luminance and desired color purity can be obtained at a low voltage.

According to the present invention, among a plurality of light-emitting elements emitting different emission colors (for example, emission colors of red (R), green (G), and blue (B)) in a light-emitting display device capable of full-color display, at least one of light-emitting elements of an emission color is a light-emitting element including an organic compound (an organic EL element), and the other light-emitting element of an emission color is a light-emitting element using an inorganic material as a light-emitting layer or a fluorescent layer (an inorganic EL element).

It is to be noted that the organic EL element and the inorganic EL element are formed over the same substrate. When the organic EL element and the inorganic EL element are formed over the same substrate, manufacturing costs per one pixel can be reduced.

In view of a light-emitting material and an element structure, in a case where all emission colors used for full-color display are formed using an inorganic EL element, it is difficult to drive all the emission colors at less than 5 to 15 V. On the other hand, the present invention has a feature in that an inorganic EL element that can drive one or two colors of those emission colors at less than 5 to 15 V is used, and an organic EL element is used for rest of the emission color.

In view of a light-emitting material and an element structure, in a case where all emission colors used for full-color display are formed using an organic EL element, it is difficult to fulfill desired luminance and lifetime of all the emission colors. On the other hand, in the present invention, for example, an organic EL element using a triplet compound can be used for one or two colors of those emission colors and an inorganic EL element with a longer lifetime than the organic EL element can be used for rest of the emission colors.

According to the present invention, a full-color display device with the long lifetime can be provided inexpensively, in which desired emission luminance can be obtained at a low voltage by combination of an organic EL element and an inorganic EL element over the same substrate. In addition, a full-color display device in which desired color purity can be obtained can be provided by appropriate combination of a color filter and an EL element. Further, according to the present invention, the number of the color filters can be reduced. For example, a full-color display device can also be manufactured using one inorganic EL element using a color filter and two organic EL elements without using a color filter. However, in order to manufacture a full-color display device with high luminance, many color filters are not desirably used from aspects of efficiency and manufacture.

An aspect of the invention disclosed in the present specification is a semiconductor device including a plurality of light-emitting elements of different emission colors in a pixel portion over a substrate, which includes a first light-emitting element of an emission color, a second light-emitting element of an emission color, and a third light-emitting element of an emission color, where an inorganic material is used as a light-emitting layer or a fluorescent layer in the first light-emitting element of an emission color, and an organic compound is included in a light-emitting layer in the second and third light-emitting elements of an emission color.

Another aspect of the invention is a semiconductor device including a plurality of light-emitting elements of different emission colors in a pixel portion over a substrate, which includes a first light-emitting element of an emission color, a second light-emitting element of an emission color, and a third light-emitting element of an emission color, where an inorganic material is used as a light-emitting layer or a fluorescent layer in the first and second light-emitting elements of an emission color, and an organic compound is included in a light-emitting layer in the third light-emitting element of an emission color.

In each of the above structures, in order to obtain a desired emission color or desired color purity, a color filter is included in a position through which light emission from the first, second, and third light-emitting elements of an emission color passes. Further, instead of the color filter, a color conversion layer may be used.

Instead of the three-color driving of RGB, four-color driving of RGBW that can improve luminance may be applied to the present invention. Another aspect of the invention is a semiconductor device including a plurality of light-emitting elements of different emission colors in a pixel portion over a substrate, which includes a first light-emitting element of an emission color, a second light-emitting element of an emission color, a third light-emitting element of an emission color, and a fourth light-emitting element of an emission color, where an inorganic material is used as a light-emitting layer or a fluorescent layer in the first light-emitting element of an emission color, and an organic compound is included in a light-emitting layer in the second, third, and fourth light-emitting elements of an emission color.

Another aspect of the invention is a semiconductor device including a plurality of light-emitting elements of different emission colors in a pixel portion over a substrate, which includes a first light-emitting element of an emission color, a second light-emitting element of an emission color, a third light-emitting element of an emission color, and a fourth light-emitting element of an emission color, where an inorganic material is used as a light-emitting layer or a fluorescent layer in the first and second light-emitting elements of an emission color, and an organic compound is included in a light-emitting layer in the third and fourth light-emitting elements of an emission color.

Another aspect of the invention is a semiconductor device including a plurality of light-emitting elements of different emission colors in a pixel portion over a substrate, which includes a first light-emitting element of an emission color, a second light-emitting element of an emission color, a third light-emitting element of an emission color, and a fourth light-emitting element of an emission color, where an inorganic material is used as a light-emitting layer or a fluorescent layer in the first, second, and third light-emitting elements of an emission color, and an organic compound is included in a light-emitting layer in the fourth light-emitting element of an emission color.

In each of the above structures of the four-color driving of RGBW, a color filter is included in a position through which light emission from the first, second, third, or fourth light-emitting element of an emission color passes. Further, instead of the color filter, a color conversion layer may be used.

As an advantage of constitution by a pixel group having four-color pixels of red, green, blue, and white, when the semiconductor device is used for application in which a white background is used with high frequency, total power consumption can be reduced. However, in a case of four-color driving of RGBW, a driver circuit for converting a three-color video signal into a four-color video signal is necessary. In addition, also, in a case of four-color driving of RGBW, a full-color display device in which desired color purity can be obtained can be provided by appropriate combination of a color filter, which is similar to a case of three-color driving of RGB. Further, in a case of four-color driving of RGBW, there is concern that saturation may be degraded by excessive emphasis of a white color in accordance with luminance or a light-emitting area of a light-emitting element used for a white pixel. Therefore, the four-color driving is appropriately adjusted in consideration of luminance or an area of a white pixel, which is preferable.

As arrangements of a pixel of RGB or RGBW, a stripe type in which light-emitting elements of the same color are arranged by pixel column units, a mosaic type in which pixels are sequentially arranged in a column direction or a row direction, a delta-type in which pixel units are arranged in zigzags in a column direction, or the like is given. An arrangement method of the pixel of the present invention is not particularly limited, and various pixel arrangements can be used.

In each of the above structures, the first emission color is red, green, blue, white, cyan, magenta, umber, orange, or yellow. Various emission colors obtained from an inorganic EL element or an organic EL element are suitably combined, whereby desired full-color display can be obtained.

As for a light-emitting device in which light-emitting elements are arranged in matrix, driving methods such as passive matrix driving (a simple matrix type) and active matrix driving (an active matrix type) can be used. The present invention can be applied to the passive matrix driving and the active matrix driving. In a case where the pixel density is increased to make a high precision panel, the active matrix type provided with switches per pixel (or one dot) has an advantage because the active matrix type can be driven at a lower voltage.

In a case of the active matrix type, a switching element such as a thin film transistor (TFT) is arranged in a pixel. As the switching element, a TFT using an amorphous silicon film, a TFT using a polysilicon film, or the like can be used. In an active matrix display device, development for extending an effective screen region in a pixel portion has been advanced. In order to extend the area of the effective screen region, an area occupied by a TFT arranged in the pixel portion (a pixel TFT) is necessary to be reduced as much as possible. In addition, development for forming a driver circuit over a substrate together with the pixel portion has been advanced in order to attempt reduction of manufacturing costs.

In a case where a light-emitting layer of an inorganic light-emitting element is formed by a film formation method with comparatively low position precision for film formation, such as a screen printing method, in an active matrix light-emitting device, it is difficult to separately coat light-emitting elements with different colors with narrow intervals in the present invention. Therefore, it is one feature of the present invention in that a structure shown in FIG. 9 as an example is made. As the feature, the same inorganic material layer is used in common for a first inorganic light-emitting element of a color and a second inorganic light-emitting element of a color adjacent to the first inorganic light-emitting element of a color. Then, the inorganic material layer is aligned with high precision and fixed with a color filter, whereby an interval between the first inorganic light-emitting element of a color and the second inorganic light-emitting element of a color that is adjacent to the first inorganic light-emitting element can be narrowed. Further, since film formation can be performed with a large width for two pixels, a full-color panel with high precision can be obtained even by a screen printing method.

Further, it is another feature of the present invention in that a material of a partition layer provided between a first organic light-emitting element of a color and a second organic light-emitting element of a color that is adjacent to the first organic light-emitting element, and a material of an insulating layer provided between a pair of electrodes of a third inorganic light-emitting element of a color are formed by the same step in an active matrix light-emitting device in order to shorten the steps. One example of this structure is shown in FIG. 10. In this case, as for the partition layer and the insulating layer, barium tantalate, silicon oxide, silicon nitride, tantalum oxide, barium titanate, or the like can be used.

In a case where full-color display is tried to be performed using an inorganic EL as a light-emitting element of a red color, a green color, or a blue color, display is performed by passive matrix driving. However, the passive matrix driver has a problem in that luminance is lowered when increasing a scanning electrode.

Further, it is another feature of the present invention in that a material of a partition layer provided between a first organic light-emitting element of a color and a second organic light-emitting element of a color that is adjacent to the first organic light-emitting element, and a material of an insulating layer provided between a pair of electrodes of a third inorganic light-emitting element of a color are formed by the same step in a passive light-emitting device in order to shorten the steps. One example of this structure is shown in FIGS. 11A and 11B. In this case, as for the partition layer and the insulating layer, barium tantalate, silicon oxide, silicon nitride, tantalum oxide, barium titanate, or the like can be used.

In a case where an inorganic material with which a comparatively high voltage for driving an inorganic EL element is 100 to 200 V, is used as a light-emitting layer or a fluorescent layer, a TFT is broken down with a voltage of 100 to 200 V, and thus it becomes difficult to use the TFT as a switching element. Accordingly, as for the light-emitting layer or the fluorescent layer used in the inorganic EL element of the present invention, an inorganic material that can be driven at a voltage of 5 to 15 V is preferably used. The inorganic EL element can obtain light emission by applying a voltage between a pair of electrodes sandwiching a light-emitting layer and can operate by either direct-current driving or alternate-current driving.

Although the inorganic EL element is classified into a dispersed inorganic EL element and a thin film-type inorganic EL element in accordance with an element structure thereof, either inorganic EL element may be used in the present invention. There is a difference that the former has an electroluminescent layer in which particles of a light-emitting material are dispersed in a binder and that the latter has an electroluminescent layer formed of a thin film of a light-emitting material. However, there is a common point that electrons accelerated in a high electric field are needed for both inorganic EL elements. As mechanism of obtained light emission, a donor-acceptor recombination emission utilizing a donor level and an acceptor level and localized emission utilizing inner shell electron transition of a metal ion are given. The donor-acceptor recombination emission is often performed in the dispersed inorganic EL, and the localized emission is often performed in the thin film-type inorganic EL element.

A light-emitting material that can be used in the present invention includes a host material and an impurity element to be a light-emitting center. When the contained impurity element is changed, various color emission can be obtained. As a manufacturing method of a light-emitting material, various methods such as a solid phase method and a liquid phase method (a coprecipitation method) can be used. Alternatively, a spraying thermal decomposition method, a double decomposition method, a method by thermal decomposition reaction of a precursor, a reversed micelle method, a method in which these methods and high temperature baking are combined, a liquid phase method such as a freeze-drying method, or the like can be used.

The solid phase method is a method in which a compound including a host material and an impurity element or a compound including the impurity element are weighed, mixed in a mortar, heated in an electric furnace and baked to react so as to include an impurity element in the host material. The baking temperature is preferably 700 to 1500° C. This is because solid-phase reaction does not proceed when temperature is too low, and the host material is decomposed when temperature is too high. The baking may be performed in a powder state; however, it is preferably performed in a pellet state. Baking at a comparatively high temperature is required. However, since it is a simple method, high productivity can be obtained; therefore, it is suitable for mass-production.

The liquid phase method (coprecepitation method) is a method in which a host material or a compound including the host material, and an impurity element or a compound including the impurity element are reacted in a solution, dried, and then baked. The particles of the light-emitting material are dispersed uniformly, and the reaction is advanced even if the particles are small and baking temperature is low.

As the host material to be used for the light-emitting material of the inorganic EL element, a sulfide, an oxide, or a nitride can be used. As a sulfide, for example, zinc sulfide (ZnS), cadmium sulfide (CdS), calcium sulfide (CaS), yttrium sulfide (Y₂S₃), gallium sulfide (Ga₂S₃), strontium sulfide (SrS), barium sulfide (BaS), or the like can be used. As an oxide, for example, zinc oxide (ZnO), yttrium oxide (Y₂O₃), or the like can be used. As a nitride, for example, aluminum nitride (AlN), gallium nitride (GaN), indium nitride (InN), or the like can be used. Further, zinc selenide (ZnSe), zinc telluride (ZnTe), or the like can be also used. Furthermore, mixed crystal of a ternary structure such as calcium sulfide-gallium (CaGa₂S₄), strontium sulfide-gallium (SrGa₂S₄), and barium sulfide-gallium (BaGa₂S₄) may be used.

As a light-emitting center of the localized emission, manganese (Mn), copper (Cu), samarium (Sm), terbium (Th), erbium (Er), thulium (Tm), europium (Eu), cerium (Ce), praseodymium (Pr), or the like can be used. As charge compensation, a halogen element such as fluorine (F) or chlorine (Cl) may be added.

On the other hand, as a light-emitting center of the donor-acceptor recombination emission, a light-emitting material including a first impurity element forming a donor level and a second impurity element forming an acceptor level can be used. As the first impurity element, for example, fluorine (F), chlorine (Cl), aluminum (Al), or the like can be used. As the second impurity element, for example, copper (Cu), silver (Ag), or the like can be used.

When a light-emitting material of donor-acceptor recombination emission is synthesized by a solid phase method, a host material, a first impurity element or a compound including the first impurity element, and a second impurity element or a compound including the second impurity element are weighed, mixed in a mortar, heated in an electric furnace and baked. As the host material, the above-described host materials can be used. As the first impurity element or the compound including the impurity element, for example, fluorine (F), chlorine (Cl), aluminum sulfide (Al₂S₃), or the like can be used. As the second impurity element or the compound including the second impurity element, for example, copper (Cu), silver (Ag), copper sulfide (Cu₂S), silver sulfide (Ag₂S), or the like can be used. The baking temperature is preferably 700 to 1500° C. This is because a solid-phase reaction does not proceed when temperature is too low, and the host material is decomposed when temperature is too high. The baking may be performed in a powder state; however, it is preferably performed in a pellet state.

As an impurity element in a case of utilizing a solid-phase reaction, a combination of compounds formed from the first impurity element and the second impurity element may be used. In this case, since the impurity element is easily dispersed and the solid-phase reaction is easily advanced, a uniform light-emitting material can be obtained. Furthermore, since impurity element is not entered excessively, the light-emitting material with high purity can be obtained. As the compound formed from the first impurity element and the second impurity element, for example, copper chloride (CuCi), silver chloride (AgCl), or the like can be used.

It is to be noted that the concentration of these impurity elements may be in the range of 0.01 to 10 atom % with respect to the host material, preferably, 0.05 to 5 atom %.

As a light-emitting material having a light-emitting center of the donor-acceptor recombination emission, a light-emitting material including the third impurity element may be used. In this case, the concentration of the third impurity element is preferably 0.05 to 5 atom % with respect to the host material. Light-emission at a low voltage is possible by using the light-emitting material having such a structure. Accordingly, a light-emitting element that can emit light at a low driving voltage can be obtained, and a light-emitting element with reduced power consumption can be obtained. Furthermore, the impurity element that is to be the light-emitting center of the localized emission may be included.

In the case of a thin film-type inorganic EL, an electroluminescent layer is a layer including the light-emitting material, and can be formed by a vacuum evaporation method such as a resistance heating vapor evaporation method or an electron-beam evaporation (EB deposition) method, a physical vapor deposition (PVD) method such as a sputtering method, an organic metal CVD method, a chemical vapor deposition method such as hydride transfer low pressure CVD method (CVD), an atomic layer epitaxy (ALE) method, or the like.

In the case of the dispersed inorganic EL, particulate light-emitting materials are dispersed in a binder to form a membranous electroluminescent layer. When a particle having a desired size cannot be sufficiently obtained, it may be processed by crushing in mortar or the like to have adequate particulate light-emitting materials. The binder is a substance for fixing the granular light-emitting material in a dispersed state, and holding in a form of an electroluminescent layer. The light-emitting material is uniformly dispersed in the electroluminescent layer by the binder and fixed.

In the case of the dispersed inorganic EL, the electroluminescent layer can be formed by a droplet discharge method in which an electroluminescent layer can be selectively formed, a printing method (screen printing, offset printing, or the like), a coating method such as spin coating, a dipping method, a dispenser method, or the like. The film thickness is not particularly limited; however, it is preferably in a range of 10 to 1000 nm. In the electroluminescent layer including a light-emitting material and a binder, the ratio of the light-emitting material is preferably greater then or equal to 50 wt % and less than or equal to 80 wt %.

Further, a conventional technique in which a full-color display device is formed by stacking a plurality of light-emission panels having different element structures and emission colors, for example, a combination of an LED of red emission and organic EL elements of green emission and blue emission, may be used. However, a total thickness of such a full-color display device becomes thick due to the panels being stacked, and a large number of components is necessary. In addition, a driving method becomes complicated because an LED array and an organic EL element array are separately driven in the full-color display device. Further, when a full-color display device is manufactured by stacking a plurality of light-emission panels, overlapping-precision is necessary to be enhanced as the full-color display device has high precision; therefore, yield is easily reduced.

A full-color display device in the present specification indicates a multicolor display panel in which light is emitted in each color gamut of red, green, and blue of a visible spectrum, and an image can be displayed by a hue of arbitral combination. By mixing light emission of three primary colors of red, green, and blue appropriately, all colors except for black can be formed.

According to the present invention, a thin-type full-color display device with the long lifetime, in which desired emission luminance and desired color purity can be obtained at a low voltage, can be provided inexpensively.

### BRIEF DESCRIPTION OF DRAWINGS

FIGS. 1A to 1C are views each showing a top view of a pixel portion of the present invention.

FIGS. 2A to 2C are views each showing an example of a cross section of a light-emitting element.

FIGS. 3A to 3C are views each showing an example of a cross section of a light-emitting element.

FIG. 4 is a view showing a perspective view of a passive display device.

FIG. 5 is a diagram showing an equivalent circuit in a pixel portion of an active matrix display device.

FIGS. 6A and 6B are views each showing a top view of a pixel portion of the present invention.

FIGS. 7A to 7E are views each showing an example of a combination of each light-emitting element and an optical filter.

FIGS. 8A to 8D are views each showing an example of a combination of each light-emitting element and an optical filter.

FIG. 9 is a view showing a cross section of an active display device.

FIG. 10 is a view showing a cross section of an active display device.

FIGS. 11A and 11B are views each showing a cross section of a passive display device.

FIGS. 12A and 12B are views each showing a top view of a module for a full-color light-emitting display.

FIGS. 13A to 13E are views each showing an example of an electronic device.

FIGS. 14A and 14B are views each showing an example of an electronic device.

### DETAILED DESCRIPTION OF THE INVENTION

Embodiment modes of the present invention will be explained below.

### EMBODIMENT MODE 1

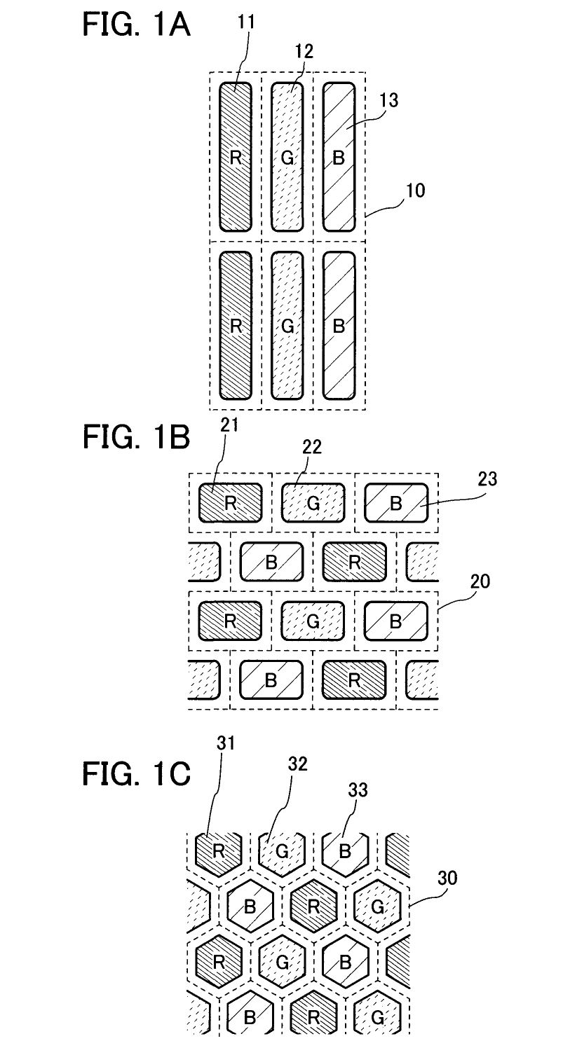

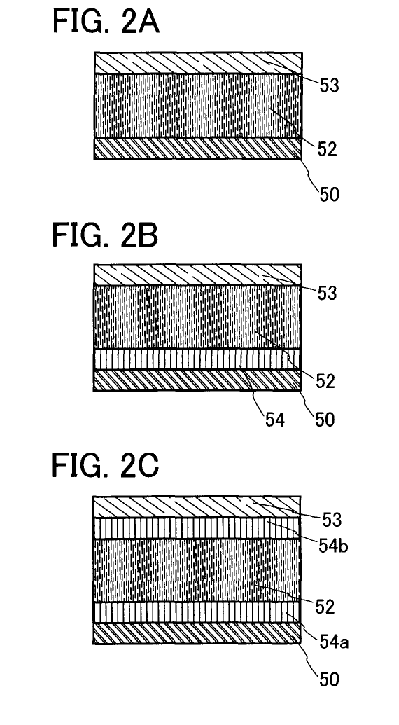

A full-color display device relating to Embodiment Mode 1 of the present invention will be explained with reference to FIG. 1A, FIGS. 2A to 2C, FIGS. 3A to 3C, FIG. 4, and FIG. 5.

FIG. 1A shows a top view of part of a pixel for performing full-color display by three-color driving of RGB. In FIG. 1A, a region surrounded by a dot line is a pixel region 10, where an organic material layer 11, an organic material layer 12, and an inorganic material layer 13, each of which is to be a light-emitting layer (or a fluorescent layer) of a light-emitting element, are formed with intervals so as not to be overlapped with each other.

Each of the organic material layer 11, the organic material layer 12, and the inorganic material layer 13 is interposed between a pair of electrodes, whereby three light-emitting elements are formed. When a voltage is applied between the pair of electrodes of each light-emitting element, the light-emitting elements each emit light of a red color, a green color, and a blue color.

Here, as the organic material layer 11 of the light-emitting element emitting red light, a material including a triplet compound is used. In a host material of the organic material layer 11, a 2,3,7,8,12,13,17,18-octaethyl-21H,23H-porphyrin-platinum complex (hereinafter, refereed to as PtOEP) that is a red phosphorescent material is used as dopant. As the host material, a hole transporting material or an electron transporting material can be used. In addition, as another host material, a bipolar material such as 4,4′-N,N′-dicarbazolyl-biphenyl (abbreviated as CBP) can also be used. Further, as another red phosphorescent material, bis(2-(2′-benzothienyl)pyridinato-N,C^{3′})(acetylacetonato)iridium (abbreviated as btp₂Ir(acac)), bis(2-(2′-thienyl)pyridinato-N,C^{3′})(acetylacetonato)iridium (abbreviated as thp₂Ir(acac)), bis(2-(1-naphthyl)benzooxazolato-N,C^{2′})(acetylacetonato)iridium (abbreviated as bon₂Ir(acac)), or the like can be given. Any of the above materials is a phosphorescent material having a reddish emission peak (greater or equal to 560 nm and less than or equal to 700 nm), and suitable for a luminous body in the organic material layer 11 of the present invention.

As the organic material layer 12 of the light-emitting element emitting green light, a material including a triplet compound is used. In a host material of the organic material layer 12, tris(2-phenylpyridine)iridium (abbreviated as Ir(ppy)₃) that is a green phosphorescent material is used as dopant. This is a phosphorescent material having a greenish emission peak (greater than or equal to 500 nm and less than or equal to 560 nm), and suitable for a luminous body in the organic material layer 12 of the present invention.

Here, an example in which the triplet compound is used in the organic material layer 11 and the organic material layer 12 is shown; however, a singlet compound may be used for either the organic material layer 11 or the organic material layer 12 instead of the triplet compound. When the singlet compound is used for the organic material layer 11 or the organic material layer 12, manufacturing costs can be reduced because a material of the singlet compound is cheap in comparison with that of the triplet compound. Further, both the triplet compound and the singlet compound may be used for the organic material layer 11 and the organic material layer 12.

In a structure of organic light-emitting elements each using the organic material layer 11 and the organic material layer 12 as a light-emitting layer, as a material used for the light-emitting layer, a single layer or a stacked layer of an organic compound is typically used. However, the present invention includes a structure in which an inorganic compound is included in part of a film made from an organic compound. A stacking-layer method for each layer in an organic light-emitting element is not limited. When the stacking-layer method is possible, any method may be selected, such as a vacuum vapor deposition method, a spin coating method, an inkjet method, and a dip-coating method.

As the inorganic material layer 13 of the light-emitting element emitting blue light, (MS)ₓ(Al₂S₃)_{y}:RE (M represents Ca, Sr, or Ba, and RE represents a rear-earth element), BaAl₂S₄:Eu, ZnS:Tm, CaGa₂S₄:Ce, SrGa₂S₄:Ce, SrS:Ag and Cu, CaS:Pb, Ba₂SiS₄:Ce, or the like can be used. Any of these materials is an inorganic material having a bluish emission peak (grater than or equal to 400 nm and less than or equal to 500 nm), and suitable for a luminous body in the inorganic material layer 13 of the present invention.

Alternatively, as the inorganic material layer 13, an inorganic material emitting bluish green light (such as SrS:Ce or SrS:Cu) or an inorganic material emitting white light (such as SrS:Ce and Eu; SrS:Ce, K, and Eu; or ZnS:Pr and Tb) may be used, and a color filter (also referred to as a color compensating filter) may be used for the light-emitting element to emit blue light. The material emitting bluish green light and the inorganic material emitting white light can be available at a low price; therefore, they are much preferable than the material emitting blue light in view of industrial production.

It is to be noted that each R, G, and B shown in FIG. 1A indicates not only light-emission color due to the light-emitting material but also light-emission color of the light-emitting element using a color filter. Further, a color filter for improving color purity of an organic EL element may be used.

As for a structure of a light-emitting element using the inorganic material layer 13, any of a dispersed inorganic EL element and a thin film-type inorganic EL element may be used.

Examples of a thin film-type inorganic EL element that can be used as a light-emitting element are shown in FIGS. 2A to 2C. In FIGS. 2A to 2C, each light-emitting element includes a first electrode layer 50, an electroluminescent layer 52, and a second electrode layer 53.

Each light-emitting element shown in FIGS. 2B and 2C has a structure in which an insulating layer is provided between the electrode layer and the electroluminescent layer in a structure of FIG. 2A. The light-emitting layer shown in FIG. 2B has an insulating layer 54 between the first electrode layer 50 and the electroluminescent layer 52. The light-emitting layer shown in FIG. 2C has an insulating layer 54a between the first electrode layer 50 and the electroluminescent layer 52 and an insulating layer 54b between the second electrode layer 53 and the electroluminescent layer 52. In such a manner, the insulating layer may be provided between the electroluminescent layer and one of a pair of the electrode layers sandwiching the electroluminescent layer. Alternatively, the insulating layers may be provided between the electroluminescent layer and each of the electrode layers sandwiching the electroluminescent layer. Further, the insulating layer may be a single layer or a stacked layer made of plural layers.

Although the insulating layer 54 is provided to be in contact with the first electrode layer 50 in FIG. 2B, the order of the insulating layer and the electroluminescent layer may be reversed so that the insulating layer 54 is provided to be in contact with the second electrode layer 53.

In the case of the dispersed inorganic EL, particulate light-emitting materials are dispersed in a binder to form a membranous electroluminescent layer. First, the light-emitting materials are processed into a particular state. When a particle having a desired size can not be obtained sufficiently by a manufacturing method of a light-emitting material, it may be processed by crushing in mortar or the like. The binder is a substance for fixing the granular light-emitting material in a dispersed state and holding in a form of an electroluminescent layer. The light-emitting material is uniformly dispersed in the electroluminescent layer by the binder and fixed.

In the case of the dispersed inorganic EL, the electroluminescent layer can be formed by a droplet discharge method in which an electroluminescent layer can be selectively formed, a printing method (screen printing, offset printing, or the like), a coating method such as spin coating, a dipping method, a dispenser method, or the like. The film thickness is not particularly limited; however, it is preferably in the range of 10 to 1000 nm. In the electroluminescent layer including a light-emitting material and a binder, the ratio of the light-emitting material may be greater than or equal to 50 wt % and less than or equal to 80 wt %.

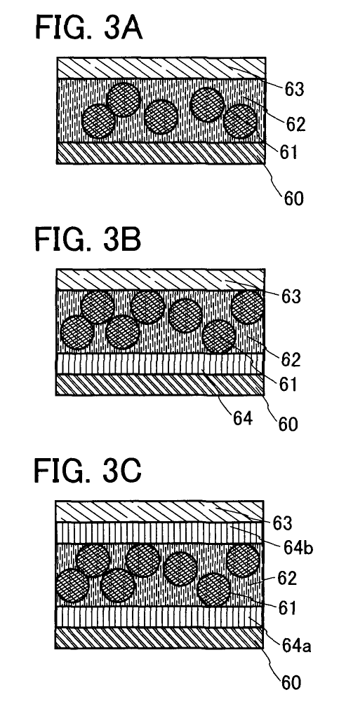

Examples of a dispersed inorganic EL that can be used as a light-emitting element are shown in FIGS. 3A to 3C. A light-emitting element in FIG. 3A has a stacked-layer structure of a first electrode layer 60, an electroluminescent layer 62, and a second electrode layer 63. In the electroluminescent layer 62, light-emitting materials 61 held by a binder are included.

As the binder that can be used for this embodiment mode, an organic material and an inorganic material can be used. In addition, a mixed material of the organic material and the inorganic material may be used. As the organic material, like a cyanoetyl cellulose resin, a polymer having a comparatively high dielectric constant, resin such as polyethylene, polypropylen, a polystyrenic resin, a silicone resin, an epoxy resin, vinylidene fluoride, or the like can be used. Alternatively, a thermally stable polymer such as aromatic polyamide and polybenzimidazole, or a siloxane resin may be used. It is to be noted that the siloxane resin corresponds to a resin having a Si—O—Si bond. In siloxane, a skeleton structure is constituted by a bond of silicon (Si) and oxygen (O). As a substituent, an organic group at least including hydrogen (for example, an alkyl group, aromatic hydrocarbon) is used. As the substituent, a fluoro group may be used. Alternatively, an organic group at least including hydrogen and a fluoro group may be used as a substituent. Alternatively, a resin material such as a vinyl resin like polyvinyl alcohol, polyvinyl butyral, or the like, a phenol resin, a novolac resin, an acrylic resin, a melamine resin, an urethane resin, or an oxazole resin (polybenz oxazole) can be used. Furthermore, a photosensitive resin, for example, a photo-curing resin may be used. The dielectric constant can be adjusted by adequately mixing fine particles of high dielectric constant such as barium titanate (BaTiO₃) or strontium titanate (SrTiO₃).

The inorganic material included in the binder can be formed of silicon oxide (SiOₓ), silicone nitride (SiNₓ), silicon including oxygen and nitrogen, aluminum nitride (AlN), aluminum including oxygen and nitrogen or aluminum oxide (Al₂O₃), titanium oxide (TiO₂), barium titanate (BaTiO₃), strontium titanate (SrTiO₃), lead titanate (PbTiO₃), potassium niobate (KNbO₃), lead niobate (PbNbO₃), tantalum oxide (Ta₂O₅), barium tantalate (BaTa₂O₆), lithium tantalate (LiTaO₃), yttrium oxide (Y₂O₃), zirconium oxide (ZrO₂), zinc sulfide (ZnS), or a material selected from a substance including other inorganic materials. By including the inorganic material having a high dielectric constant in the organic material (by addition or the like), the dielectric constant of the electroluminescent layer made from the light-emitting material and the binder can be controlled further, and the dielectric constant can be increased further.

In a manufacturing step, a light-emitting material is dispersed in a solution including a binder. As a solvent of a solution including the binder that can be used for this embodiment mode, a solvent in which a binder material is dissolved, and a solution having a viscosity suitable for a method for forming an electroluminescent layer (various wet processes) and for a desired film thickness can be formed, may be appropriately selected. In a case where the organic solvent or the like can be used, for example, a siloxane resin is used as a binder, propylene glycol monomethylether, propylene glycol monomethylether acetate (also referred to as PGMEA), 3-methoxy-3-methyl-1-butanol (also referred to as MMB), or the like can be used.

Each light-emitting element shown in FIGS. 3B and 3C has a structure in which an insulating layer is provided between an electrode layer and an electroluminescent layer in a light-emitting element of FIG. 3A. The light emitting element shown in FIG. 3B has an insulating layer 64 between the first electrode layer 60 and the electroluminescent layer 62. The light-emitting element shown in FIG. 3C has an insulating layer 64a between the first electrode layer 60 and the electroluminescent layer 62, and an insulating layer 64b between the second electrode layer 63 and the electroluminescent layer 62. In such a manner, the insulating layer may be provided between the electroluminescent layer and one of the electrode layers sandwiching the electroluminescent layer. Alternatively, the insulating layers may be provided between the electroluminescent layer and each of the electrode layers. Further, the insulating layer may be a single layer or a stacked layer formed of a plural layers.

Although the insulating layer 64 is provided to be in contact with the first electrode layer 60 in FIG. 3B, the order of the insulating layer and the electroluminescent layer may be reversed so that the insulating layer 64 is provided to be in contact with the second electrode layer 63.

An insulating layer such as the insulating layer 54 in FIGS. 2A to 2C and the insulating layer 64 in FIGS. 3A to 3C is not particularly limited. However, it preferably has a high dielectric strength, a fine film quality, and a high dielectric constant. For example, silicon oxide (SiO₂), yttrium oxide (Y₂O₃), titanium oxide (TiO₂), aluminum oxide (Al₂O₃), hafnium oxide (HfO₂), tantalum oxide (Ta₂O₅), barium titanate (BaTiO₃), strontium titanate (SrTiO₃), lead titanate (PbTiO₃), silicon nitride (Si₃N₄), or zirconium oxide (ZrO₂), or the like, a mixed film thereof, a stacked film including two or more kinds thereof can be used. These insulating films can be formed by sputtering, evaporation, CVD, or the like. The insulating layer may be also formed by dispersing particles of these insulating materials in a binder. The material for the binder is formed of the same material as the binder included in the electroluminescent layer using the same method. The film thickness is not particularly limited; however, it is preferably in the range of 10 to 1000 nm.

In such a manner, the light-emitting element using the inorganic material for a light-emitting layer and the light-emitting element using the organic material for a light-emitting layer are formed over the same substrate, and characteristics of each light-emitting element is adequately combined to be used, whereby display with a wide range of full-color reproduction can be performed. Further, since an energy level of a triplet excited state is lower than that of a singlet excited state, phosphorescence in a wavelength band of green to red colors on the long wavelength side can be obtained. On the other hand, the organic EL element has difficulty in obtaining blue phosphorescence. Therefore, it can be said that a pixel structure of this embodiment mode in which blue light emission is obtained from an inorganic EL element is an optimal combination.

In the light-emitting element shown in this embodiment mode, light emission can be obtained by applying a voltage between a pair of electrode layers sandwiching an electroluminescent layer. Further, the light-emitting element of this embodiment mode can operate by either direct-current driving or alternate-current driving.

In the case of a passive display device, a first wiring extending in parallel to a first direction and a second wiring extending in parallel to a second direction that is perpendicular to the first direction are arranged in the pixel region 10. In the passive display device, alternate-current driving is performed by combining a first electrode electrically connected to the first wiring and a second electrode electrically connected to the second wiring as a pair.

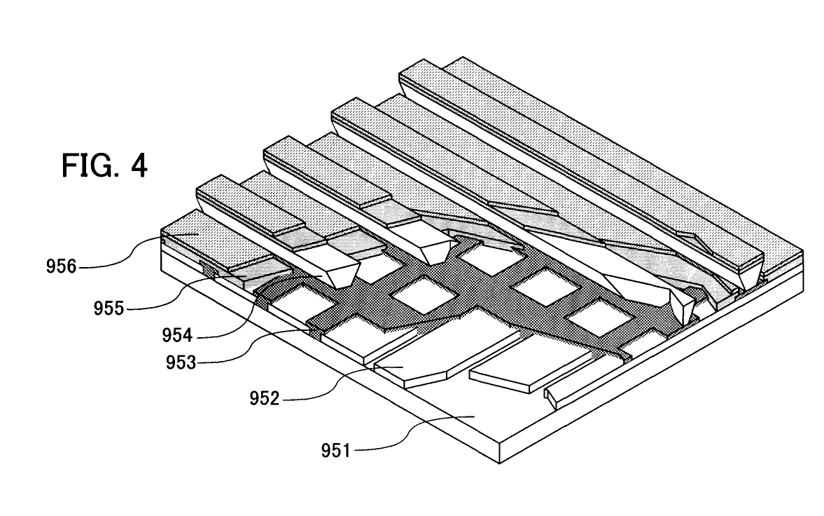

FIG. 4 shows a perspective view of a passive display device that is manufactured by application of the present invention. In FIG. 4, three kinds of light-emitting elements having a structure in which a layer 955 including a light-emitting layer and the like is provided between a first electrode 952 and a second electrode 956 is formed over a substrate 951. In order to perform full-color display by three-color driving of RGB, the light-emitting elements respectively having the organic material layer 11, the organic material layer 12, or the inorganic material layer 13 as a light-emitting layer or a fluorescent layer, are provided. An edge portion of the first electrode 952 is covered with an insulating layer 953. Further, a partition layer 954 is provided over the insulating layer 953. A side wall of the partition layer 954 has such a gradient that the distance between one side wall and the other side wall becomes narrower toward the substrate surface. That is to say, a cross section of the partition layer 954 in a short side direction has a trapezoidal shape, in which a bottom side (a side in a similar direction to a surface direction of the insulating layer 953, which is in contact with the insulating layer 953) is shorter than an upper side (a side in a similar direction to the surface direction of the insulating layer 953, which is not in contact with the insulating layer 953). By the partition layer 954 thus being provided, defects of a light-emitting element due to static electricity and the like can be prevented.

In the case of the passive display device, a driving condition where luminance of the inorganic EL element is saturated, specifically, a high voltage (15 V or more), can be applied to the inorganic EL element, whereby display with high luminance can be obtained. In addition, in the passive display device, a reverse bias voltage after a forward bias driving is applied, whereby decrease in luminance can be moderated. Further, when the structure of the present invention of a combination of the organic EL element and the inorganic EL element is made, it is possible to obtain a thin-type passive full-color display device with the long lifetime, in which desired color purity can be obtained.

In the case of an active display device, a first wiring extending in parallel to a first direction, a second wiring extending in parallel to a second direction that is perpendicular to the first direction, and a switching element are arranged in the pixel region 10.

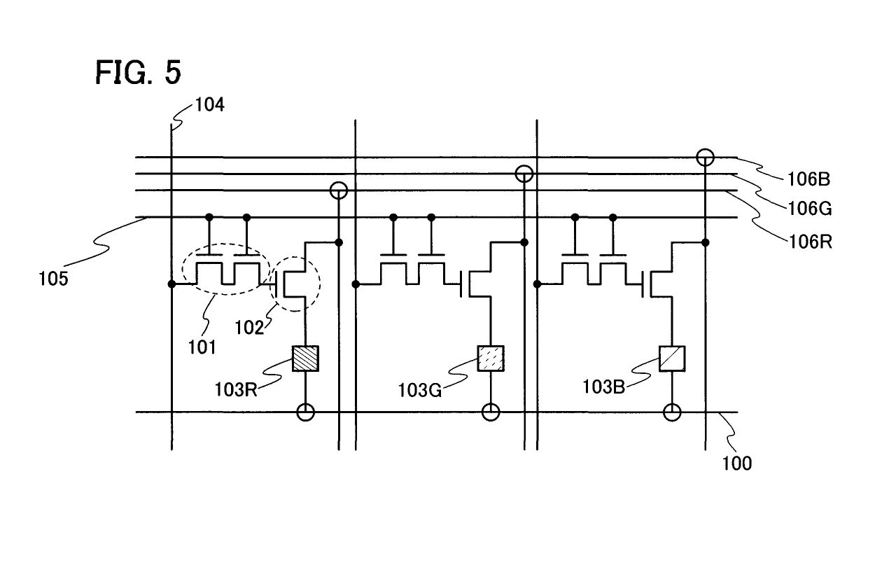

FIG. 5 shows an equivalent circuit diagram of an active display device in which a TFT is used as a switching element. In FIG. 5, reference numeral 101 denotes a switching TFT, and reference numeral 102 denotes a current control TFT. In a pixel displaying a red color, an organic EL element 103R emitting red light is connected to a drain region of the current control TFT 102, and an anode-power supply line (R) 106R is provided in a source region thereof. In addition, a cathode-power supply line 100 is provided in the organic EL element 103R. In a pixel displaying a green color, an organic EL element 103G emitting green light is connected to a drain region of the current control TFT, and an anode-power supply line (G) 106G is provided in a source region thereof. In a pixel displaying a blue color, an inorganic EL element 103B emitting blue light is connected to a drain region of the current control TFT, an anode-power supply line (B) 106B is provided in a source region thereof. Different voltages are applied to the pixels displaying different colors from each other depending on EL materials. It is to be noted that, when an inorganic EL element that can be driven by a comparatively low voltage (less than 15 V) is used, a structure of the present invention where an organic EL element and an inorganic EL element are combined can be achieved. The active driving can reduce one pixel size while high luminance is held; therefore, color display with high precision can be achieved.

Pixels can be arranged in various ways, which is another advantage of the active driving. Although the example of a mosaic-type in which pixels are sequentially arranged in a column direction or a row direction is shown in FIG. 1A, a delta-type in which pixel units are arranged in zigzags in a column direction, or a stripe-type in which light-emitting elements of the same color are arranged by pixel column units may be made.

### EMBODIMENT MODE 2

In this embodiment mode, an example of a delta-type pixel arrangement is shown in FIG. 1B, in which an interval between pixels adjacent to each other can be narrowed.

In a pixel structure of this embodiment mode, an inorganic EL element emitting green light is used, which has a different emission color from that of the inorganic EL element in Embodiment Mode 1. This embodiment mode shows an example of performing full-color display by a pixel structure in which an inorganic EL element emitting green light, an organic EL element emitting blue light, and an organic EL element emitting red light are used.

In FIG. 1B, a region surrounded by a dot line is a pixel region 20 where an organic material layer 21, an inorganic material layer 22, and an organic material layer 23, each of which is to be a light-emitting layer (or a fluorescent layer) of a light-emitting element, are formed with keeping intervals so as not to be overlapped with each other.

Here, as the organic material layer 21 of a light-emitting element emitting red light, a material including a triplet compound is used. As for the organic material layer 21 of the light-emitting element emitting red light, the same material as that of the organic material layer 11 shown in Embodiment Mode 1 can be used.

As the organic material layer 23 of a light-emitting element emitting blue light, a material including a triplet compound such as (4,6-F2 ppy)2Irpic or a Ir compound having a fluorinated ppy ligand structure as a basis can be used. However, since (4,6-F2 ppy)2Irpic has an emission color that is close to light blue (cyan), color purity is preferably improved with the use of a color filter. Further, an energy level of a triplet excited state is lower than that of a singlet excited state; therefore, it is difficult to obtain phosphorescence in a wavelength band of a blue color. Accordingly, a blue-color material emitting fluorescence, for example, perylene, may be used for the organic material layer 22 of the light-emitting element emitting blue light.

As the inorganic material layer 22 of a light emitting element emitting green light, ZnS:Tb, SrGa₂S₄:Eu, CaAl₂S₄:Eu, or the like can be used.

An inorganic material emitting bluish green light (SrS:Ce, SrS:Cu, or the like) or an inorganic material emitting white light (SrS:Ce and Eu; ZnS:Pr and Tb; or the like) is used as the inorganic material layer 22, and a color filter may be applied to the light-emitting element of the inorganic material layer, whereby green light-emission is obtained.

In such a manner, the light-emitting element using the inorganic material for the light-emitting layer and the light-emitting element using the organic material for the light-emitting layer are formed over the same substrate, and characteristics of each light-emitting element is adequately combined to be used, whereby display with a wide range of full-color reproduction can be performed.

In the light-emitting element shown in this embodiment mode, light-emission can be obtained by applying a voltage between a pair of electrode layers sandwiching an electroluminescent layer. Further, the light-emitting element of this embodiment mode can operate by either direct-current driving or alternate-current driving.

The pixel structure shown in this embodiment mode can be applied to any of a passive display device and an active display device.

This embodiment mode can be freely combined with Embodiment Mode 1.

### EMBODIMENT MODE 3

In this embodiment mode, an example of arrangement of a light-emitting element will be shown in FIG. 1C, in which a shape of a light-emitting region is not rectangle but hexagon.

In a pixel structure of this embodiment mode, an inorganic EL element emitting red light is used, which has a different emission color from that of the inorganic EL element in Embodiment Mode 1. This embodiment mode shows an example of performing full-color display by a pixel structure in which this inorganic EL element emitting red light, an organic EL element emitting blue light, and an organic EL element emitting green light are used.

In FIG. 1C, a region surrounded by a dot line is a pixel region 30 where an inorganic material layer 31, an organic material layer 32, and an organic material layer 33, each of which is to be a light-emitting layer (or a fluorescent layer) of a light-emitting element, are formed with keeping intervals so as not to be overlapped with each other.

Here, as the inorganic material layer 31 of a light-emitting element emitting red light, Zn:Sm, CaS:Eu, Ba₂ZnS₃:Mn or (Ca, Sr)Y₂S₄:Eu, or ZnGa₂O₄:Eu, or the like can be used.

Alternatively, as the inorganic material layer 31, ZnS:Mn is used, and a color filter may be applied to a light-emitting element of an umber color, whereby red emission is obtained.

As the organic material layer 32 of a light-emitting element emitting green light, a material including a triplet compound is used. As the organic material layer 32 of the light-emitting element emitting green light, the same material as that of the organic material layer 12 shown in Embodiment Mode 1 can be used.

As the organic material layer 33 of a light-emitting element emitting blue light, a material including a triplet compound is used. As the organic material layer 33 of the light-emitting element emitting blue light, the same material as that of the organic material layer 23 shown in Embodiment Mode 2 can be used.

In such a manner, the light-emitting element using the inorganic material for the light-emitting layer and the light-emitting element using the organic material for the light-emitting layer are formed over the same substrate, and characteristics of each light-emitting element is adequately combined to be used, whereby display with a wide range of full-color reproduction can be performed.

In the light-emitting element shown in this embodiment mode, light-emission can be obtained by applying a voltage between a pair of electrode layers sandwiching an electroluminescent layer. Further, the light-emitting element of this embodiment mode can operate by either direct-current driving or alternate-current driving.

The pixel structure shown in this embodiment mode can be applied to any of a passive display device and an active display device.

This embodiment mode can be freely combined with Embodiment Mode 1 or Embodiment Mode 2.

### EMBODIMENT MODE 4

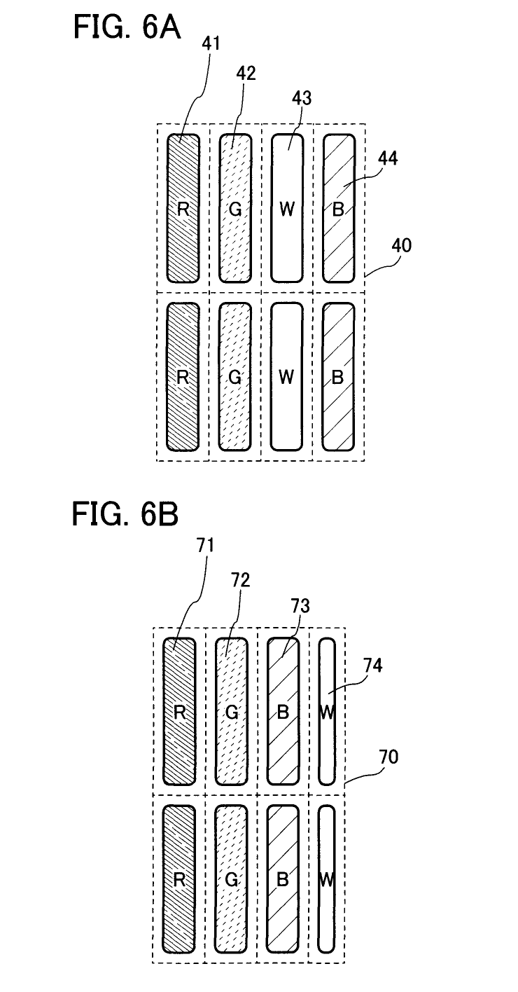

An example in which the present invention is applied to four-pixel driving of RGBW will be explained with reference to FIG. 6A. FIG. 6A shows a top view of part of a pixel that performs full-color display by four-color driving of RGBW. It is to be noted that, in the case of four-color driving of RGBW, a driver circuit is necessary for converting a three-color video signal into a four-color video signal.

In FIG. 6A, a region surrounded by a dot line is a pixel region 40 where an organic material layer 41, an organic material layer 42, an organic material layer 43, and an inorganic material layer 44, each of which is to be a light-emitting layer (or a fluorescent layer), are formed with keeping intervals so as not to be overlapped with each other.

Each of the organic material layer 41, the organic material layer 42, the organic material layer 43, and the inorganic material layer 44 are interposed between a pair of electrodes, whereby four light-emitting elements are formed. When a voltage is applied between the pair of the electrodes of each light-emitting element, the light-emitting elements respectively emit red light, green light, blue light, and white light.

Here, as the organic material layer 41 of the light-emitting element emitting red light, a material including a triplet compound is used. As the organic material layer 41 of the light-emitting element emitting red light, the same material as that of the organic material layer 11 shown in Embodiment Mode 1 can be used.

As the organic material layer 42 of the light-emitting element emitting green light, a material including a triplet compound is used. As the organic material layer 42 of the light-emitting element emitting green light, the same material as that of the organic material layer 12 shown in Embodiment Mode 1 can be used.

As the organic material layer 43 of the light-emitting element emitting white light, a plurality of coloring matters can be used, for example, a single light-emitting layer doped with each coloring matter of RGB, or a light-emitting layer made of two or more stacked layers including a different coloring matter from each other. An organic EL element emitting white light can employ various structures. For example, in a case of using a light-emitting layer made form a high molecular material, a 1,3,4-oxiadiazole derivative (PBD) having an electron transporting property may be dispersed in polyvinylcarbazole (PVK) having a hole transporting property. In addition, PBD of 30 wt % is dispersed into PVK as an electron transporting agent, and then the adequate amount of coloring matters having four kinds (TPB, coumarin 6, DCM 1, and Nile Red) is dispersed, whereby white emission can be obtained. Alternatively, in a case of using a light-emitting layer made from a low molecular material, CuPc, α-NPD, CBP that includes an organic metal complex (Pt(ppy)acac) using platinum as a central metal, BCP, and BCP:Li can be sequentially stacked. A light-emitting element using this stacked layer generates white emission by emitting blue emission, phosphorescence emission from the organic metal complex, and light-emission from an excimer state of the organic metal complex together. It is to be noted that CBP is an abbreviation designation of 4,4′-N,N′-dicarbazolyl-biphenyl. The triplet compound represented by Pt(ppy)acac emits light efficiently and is effective in a large-sized panel.

In addition, in a case where a single light-emitting layer doped with a plurality of coloring matters is used as the organic material layer 43 of the light-emitting element emitting white light, the light-emitting element includes at least two or more kinds of light-emitting center materials. In the plural light-emitting center materials, at least one or more kind of materials can be a phosphorescent emitting material, and at least one of more of kind of materials can be a fluorescent emitting material.

As the inorganic material layer 44 of the light-emitting element emitting blue light, the same material as that of the inorganic material layer 13 shown in Embodiment Mode 1 can be used. Further, an inorganic material emitting bluish green emission (SrS:Ce, SrS:Cu, or the like) or an inorganic material emitting white emission (SrS:Ce and Eu; SrS:Cu, K, and Eu; ZnS:Pr and Tb; or the like) is used for the inorganic material layer 44, and a color filter (also referred to as a color compensation filter) may be applied to the light-emitting element, whereby blue emission is obtained.

In such a manner, the light-emitting element using the inorganic material for the light-emitting layer and the light-emitting element using the organic material for the light-emitting layer are formed over the same substrate, and characteristics of each light-emitting element is adequately combined to be used, whereby display with a wide range of full-color reproduction can be performed.

In the light-emitting element shown in this embodiment mode, light emission can be obtained by applying a voltage between a pair of electrode layers sandwiching an electroluminescent layer. Further, the light-emitting element of this embodiment mode can operate by either direct-current driving or alternate-current driving.

The pixel structure shown in this embodiment mode can be applied to any of a passive display device and an active display device.

This embodiment mode can be freely combined with Embodiment Mode 1, Embodiment Mode 2, or Embodiment Mode 3.

### EMBODIMENT MODE 5

In this embodiment mode, another example of four-pixel driving of RGBW will be explained with reference to FIG. 6B. In this embodiment mode, an example in which four pixels of RGBW do not have the same light-emitting area is shown. In a case of four-pixel driving of RGBW, when each pixel has the same light emitting area, there is possibility that a white color is excessively emphasized and saturation is degraded. Therefore, a light-emitting area of a white color is made to be smaller than other light-emitting areas in this embodiment mode. In addition, in order to achieve an optimal full-color display, the light-emitting areas of other emission colors may be appropriately adjusted without limitation of the light-emitting area of a white color.

In a pixel structure of this embodiment mode, organic EL elements respectively emitting red light and green light are used, which has the different emission color from the organic EL element in Embodiment Mode 4. This embodiment mode shows an example of performing full-color display by a pixel structure in which the organic EL element emitting red light, the organic EL element emitting green light, an inorganic EL element emitting blue light, and an inorganic EL element emitting white light are used. The organic EL element has difficulty in emitting white light or blue light efficiently in accordance with the problem of the material. Therefore, a structure in which the white or blue light is efficiently emitted by the inorganic EL element is desirable as shown in this embodiment mode.

In FIG. 6B, a region surrounded by a dot line is a pixel region 70 where an organic material layer 71, an organic material layer 72, an inorganic material layer 73, and an inorganic material layer 74, each of which is to be a light-emitting layer (or a fluorescent layer) of a light-emitting element, are formed with keeping intervals so as not to be overlapped with each other.

Here, as the organic material layer 71 of a light-emitting element emitting red light, a material including a triplet compound is used. As the organic material layer 71 of the light-emitting element emitting red light, the same material as that of the organic material layer 11 shown in Embodiment Mode 1 can be used.

As the organic material layer 72 of a light-emitting element emitting green light, a material including a triplet compound is used. As the organic material layer 72 of the light-emitting element emitting green light, the same material as that of the organic material layer 12 shown in Embodiment Mode 1 can be used.

As the inorganic material layer 73 of a light-emitting element emitting blue light, the same material as that of the inorganic material layer 13 shown in Embodiment Mode 1 can be used. Further, an inorganic material emitting bluish green light (SrS:Ce, SrS:Cu, or the like) or an inorganic material emitting white light (SrS:Ce and Eu; SrS:Ce, K, and Eu; ZnS:Pr and Tb; or the like) is used for the inorganic material layer 73, and a color filer (also referred to as a color compensation filter) may be applied to the light-emitting element, whereby blue emission is obtained.

As the inorganic material layer 74 of the light-emitting element emitting white emission, SrS:Ce and Eu; SrS:Ce, K, and Eu; ZnS:Pr and Tb; or the like can be used.

In the pixel arrangement of FIG. 6B, the light-emitting element emitting blue light and the light-emitting element emitting white light are arranged to be adjacent to each other. Therefore, the same inorganic material may be used for the two light-emitting elements to make white light emission, and a blue color filter may be used for one of the light-emitting elements. By using the same material, manufacturing steps can be simplified, and material costs can be reduced. As such a white light-emitting material, a light-emitting material can be used, for example, which includes ZnS as a host material, Cl as a first impurity element, Cu as a second impurity element, Ga and As as third impurity elements, and Mn as a light-emitting center of localized emission. In order to form such a white light-emitting material, a method described below can be used. Mn is added to a light-emitting material (Zn:Cu and Cl) and baked in vacuum for approximately 2 to 4 hours. The baking temperature is preferably set to be 700 to 1500° C. The baked material is crushed to be particles each having a grain size of 5 to 20 μm, and GaAs with a grain size of 1 to 3 μm is added thereto to be stirred. This mixture is baked in a nitrogen gas stream including a sulfur gas at about 500 to 800° C. for 2 to 4 hours, whereby the light-emitting material can be obtained. When a thin film is formed by an evaporation method or the like with the use of the white light-emitting material, the thin film can be used for a light-emitting layer of the light-emitting element emitting white light.

Here, although an example in which the inorganic EL element is used for two pixels among four pixels, the present invention is not particularly limited thereto. The inorganic EL element may be used for three pixels, and an organic EL element may be used for the last one pixel.

In such a manner, the light-emitting element using the inorganic material layer for the light-emitting layer and the light-emitting element using the organic material for the light-emitting layer are formed over the same substrate, and characteristics of each light-emitting element are adequately combined to be used, whereby display with a wide range of full-color reproduction can be performed.

In the light-emitting element shown in this embodiment mode, light emission can be obtained by applying a voltage between a pair of electrode layers sandwiching an electroluminescent layer. Further, the light-emitting element of this embodiment mode can operate by either direct-current driving or alternate-current driving.

The pixel structure shown in this embodiment mode can be applied to any of a passive display device or an active display device.

This embodiment mode can be freely combined with Embodiment Mode 1, Embodiment Mode 2, Embodiment Mode 3, or Embodiment Mode 4.

### EMBODIMENT MODE 6

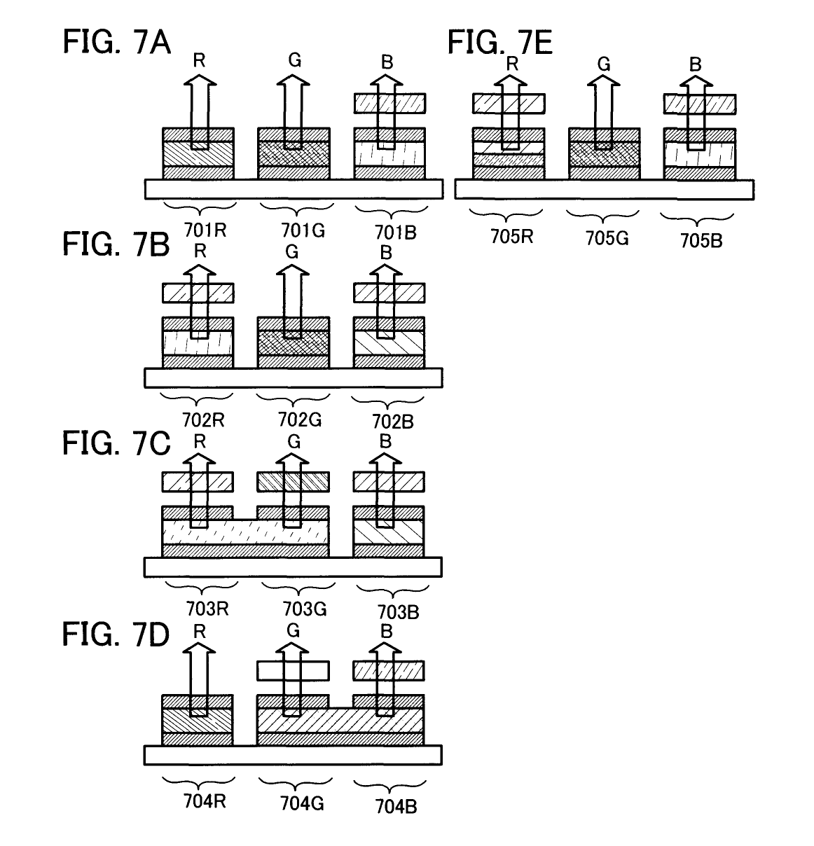

Here, in a case of performing full-color display by three-color driving of RGB, a combination of a color filter and a light-emitting element to be used will be explained with reference to schematic views (FIGS. 7A to 7E).

FIG. 7A is a schematic view in which a red light-emitting element 701R, a green light-emitting element 701G, and a blue light-emitting element 701B are provided over the same substrate. FIG. 7A shows a structure in which a single layer of a light-emitting layer is interposed between a pair of electrodes; however, it is just one typical view. A stacked-layer structure may be employed, and further, an inorganic light-emitting element may have the structures shown in FIGS. 2A to 2C and FIGS. 3A to 3C.

FIG. 7A shows a combination example in which each of the red light-emitting element 701R and the green light-emitting element 701G is an organic light-emitting element, and the blue light-emitting element 701B is a white (or cyan) inorganic light-emitting element using a blue color filter.

FIG. 7B shows a combination example in which a red light-emitting element 702R is an orange inorganic light-emitting element using a red color filter, a green light-emitting element 702G is an organic light-emitting element, and a blue light-emitting element 702B is a white (or cyan) organic light-emitting element using a blue color filter.

FIG. 7C shows a combination example in which a red light-emitting element 703R is an orange inorganic light-emitting element using a red color filter, a green light-emitting element 703G is an orange inorganic light-emitting element using a green color filter, and a blue light-emitting element 703B is a white (or cyan) organic light-emitting element using a blue color filter. In FIG. 7C, a common light-emitting layer can be used for the red light-emitting element and the green light-emitting element; therefore, manufacturing steps can be shortened. In addition, by using the common light-emitting element, an interval between the red light-emitting element 703R and the green light-emitting element 703G can be narrowed.

FIG. 7D shows a combination example in which a red light-emitting element 704R is an organic light-emitting element, a green light-emitting element 704G is a blue inorganic light-emitting element using a color conversion layer that makes green light, and a blue light-emitting element 704B is a blue inorganic light-emitting element in which color purity is improved by using a blue color filter. A method for converting a color into a desired color with the use of a color conversion layer is one of the methods for changing a color tone of light, which is a method (hereinafter, also referred to as a CCM method) in which blue emission obtained in a light-emitting layer is used as a light-emitting source, and the emission color is converted into a desired color in the color conversion layer formed from a color conversion material. In FIG. 7D, a common light-emitting layer can be used for the green light-emitting element and the blue light-emitting element; therefore, manufacturing steps can be shortened.

FIG. 7E shows a combination example of a red light-emitting element 705R, a green light-emitting element 705G, and a blue light-emitting element 705B. In the red light-emitting element 705R, a first light-emitting layer emitting orange light (MnS:Mn) and a second light-emitting layer emitting green light (MnS:Tb) are stacked, and further, a red color filter is used. The green light-emitting element 705G is an organic light-emitting element. The blue light-emitting element 705B is a white (or cyan) inorganic light-emitting element using a blue color filter.

In such a manner, various combinations are possible in the present invention. The practitioner may select an optimal combination for desired full-color display, appropriately.

In FIGS. 7A to 7E, the schematic views in which the color filter or the color conversion layer is arranged to have an interval from the light-emitting element are shown. However, a color filter or a color conversion layer may be formed so as to be in contact with the light-emitting element, or another optical film or a substrate for sealing may be provided between the light-emitting element and the color filter.

FIGS. 7A to 7E show structures in which light emission of each color is emitted to the upper side of the light-emitting element provided over the substrate. However, a structure of the present invention is not particularly limited, and a structure in which light is emitted to the bottom side of the light-emitting element with the use of a light-transmitting substrate may be employed. In a case of employing the structure in which light is emitted to the bottom side, a color filter or a color conversion layer is provided on a rear surface side of the substrate.

Further, a structure may be employed, in which light is emitted to both upper side and bottom side of the light-emitting element with the use of transparent conductive films as a pair of electrodes of the light-emitting element. In a case of the structure in which light is emitted to the both sides to perform full-color display on the both sides, color filters or color conversion layers may be provided on both sides.

This embodiment mode can be freely combined with Embodiment Mode 1, Embodiment Mode 2, or Embodiment Mode 3.

### EMBODIMENT MODE 7

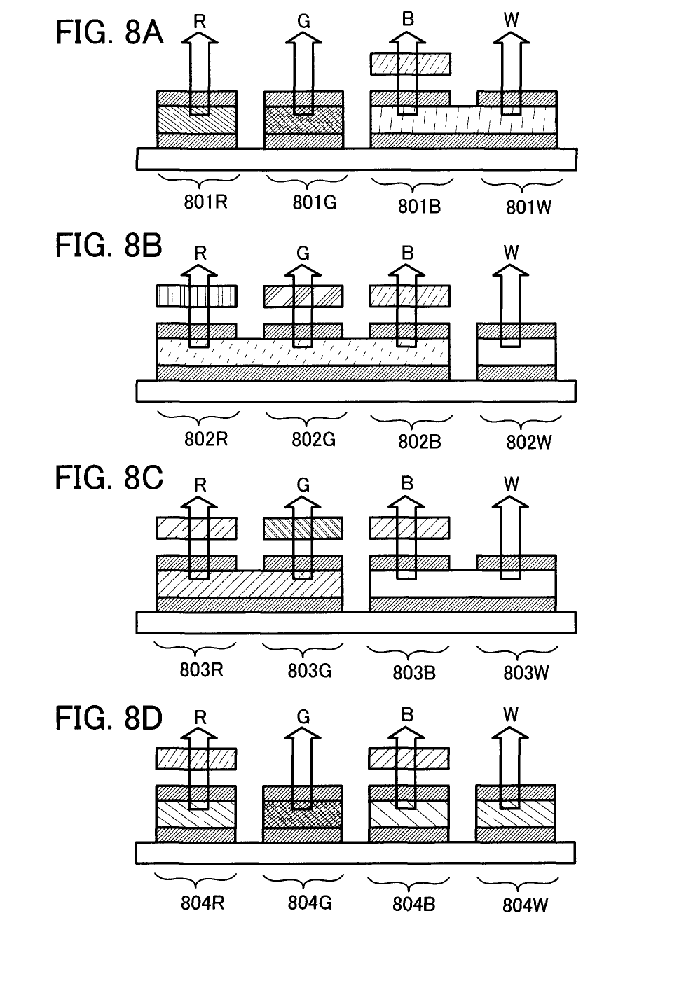

Here, in a case of full-color display by four-color driving of RGBW, a combination of a color filter and a light-emitting element to be used will be explained with schematic views (FIGS. 8A to 8D).

FIG. 8A is a schematic view in which a red light-emitting element 801R, a green light-emitting element 801G, a blue light-emitting element 801B, and a white light-emitting element 801W are provided over the same substrate. FIG. 8A shows a structure in which a single layer of a light-emitting layer is interposed between a pair of electrodes; however, it is just one typical structure. A stacked-layer structure may be employed, and the inorganic light-emitting element may have the structures shown in FIGS. 2A to 2C and FIGS. 3A to 3C.

FIG. 8A shows a combination example in which each of the red light-emitting element 801R and the green light-emitting element 801G is an organic light-emitting element, the blue light-emitting element 801B is a white inorganic light-emitting element using a blue color filter, and the white light-emitting element 801W is a white inorganic light-emitting element. In FIG. 8A, a common light-emitting layer can be used for the blue light-emitting element and the white light-emitting element; therefore, manufacturing steps can be shortened.

FIG. 8B shows a combination example of a red light-emitting element 802R, a green light-emitting element 802G; a blue light-emitting element 802B, and a white light-emitting element 802W. The red light-emitting element 802R is a blue inorganic light-emitting element using a color conversion layer that makes red emission. The green light-emitting element 802G is a blue inorganic light-emitting element using a color conversion layer that makes green emission. The blue light-emitting element 802B is a blue inorganic light-emitting element using a blue color filter for improving color purity. The white light-emitting element 802W is a white organic light-emitting element. In FIG. 8B, a common light-emitting layer can be used for the red light-emitting element, the blue light-emitting element, and the green light-emitting element; therefore, manufacturing steps can be shortened.

FIG. 8C shows a combination example of a red light-emitting element 803R, a green light-emitting element 803Q a blue light-emitting element 803B, and a white light-emitting element 803W. The red light-emitting element 803R is an orange inorganic light-emitting element using a red color filter. The green light-emitting element 803G is an orange inorganic light-emitting element using a green color filter. The blue light-emitting element 803B is a white organic light-emitting element using a blue color filter. The white light-emitting element 803W is a white organic light-emitting element. In FIG. 8C, a first common light-emitting layer can be used for the red light-emitting element and the green light-emitting element, and a second common light-emitting layer can be used for the blue light-emitting element and the white light-emitting element; therefore, manufacturing steps can be shortened. In addition, by using the common light-emitting layer, an interval between the red light-emitting element 803R and the green light-emitting element 803G can be narrowed.

FIG. 8D shows a combination example of a red light-emitting element 804R, a green light-emitting element 804Q a blue light-emitting element 804B, and a white light-emitting element 804W. The red light-emitting element 804R is a blue inorganic light-emitting element using a red color filter. The green light-emitting element 804G is an organic light-emitting element. The blue light-emitting element 804B is a white (or cyan) organic light-emitting element using a blue color filter. The white light-emitting element 804W is a white inorganic light-emitting element.

In such a manner, various combinations are possible in the present invention. The practitioner may select an optimal combination for desired full-color display, appropriately.

In FIGS. 8A to 8D, the schematic views in which the color filter or the color conversion layer is arranged to have an interval from the light-emitting element are shown. However, the color filter or the color conversion layer may be formed so as to be in contact with the light-emitting element, or another optical film or a substrate for sealing may be provided between the light-emitting element and the color filter.

FIGS. 8A to 8D show structures in which light emission of each color is emitted to the upper side of the light-emitting element provided over the substrate. However, a structure of the present invention is not particularly limited, and a structure in which light is emitted to the bottom side of the light-emitting element with the use of a light-transmitting substrate may be employed. In a case of a structure in which light is emitted to the bottom side, the color filter or the color conversion layer is provided on a rear surface side of the substrate.

Further, a structure may be employed, in which light is emitted to both upper side and bottom side of the light-emitting element with the use of transparent conductive films as a pair of electrodes of the light-emitting element. In a case of the structure in which light is emitted to the both sides to perform full-color displays on the both sides, color filters or color conversion layers may be provided on both sides.

This embodiment mode can be freely combined with Embodiment Mode 4 or Embodiment Mode 5.

### EMBODIMENT MODE 8

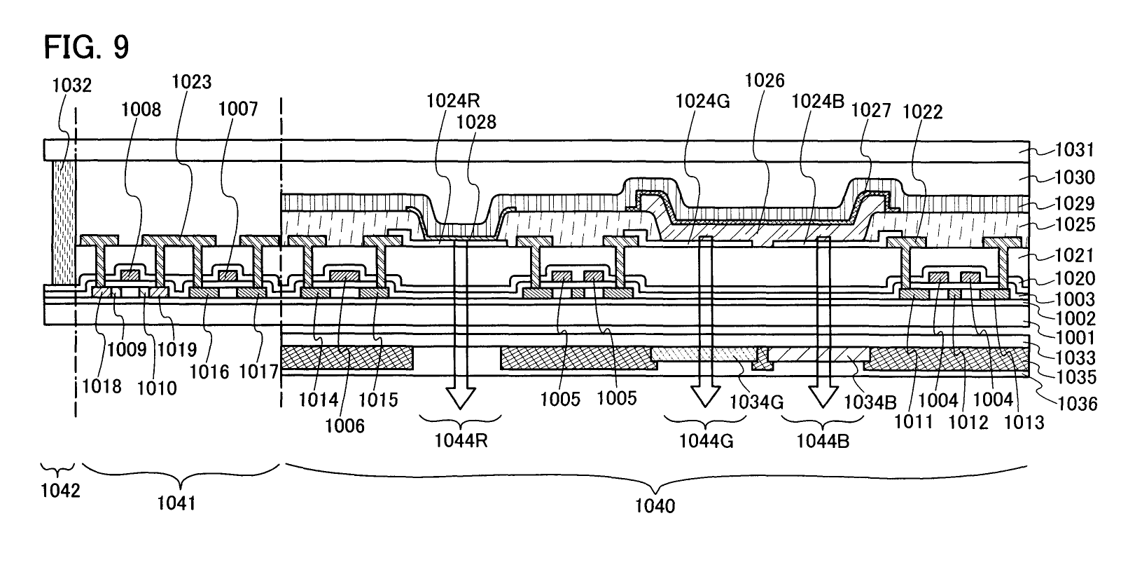

Here, an example of a manufacturing step of an active display device will be explained with reference to FIG. 9.

First, a base insulating film 1002 is formed over a substrate 1001. This is an example in which light emission is extracted from the substrate 1001 side set as a display surface. Therefore, a glass substrate or a quartz substrate having a light-transmitting property may be used for the substrate 1001. Alternatively, a light-transmitting plastic substrate having heat resistance to the processing temperature may be used.

As the base insulating film 1002, a base film made of an insulating film such as a silicon oxide film, a silicon nitride film, or a silicon oxynitride film. Here, an example in which a two-layer structure is used as a base film is shown; however, a structure of a single film of the insulating film or a stacked-layer having two or more of the insulating films may be used. It is to be noted that the base insulating film may not be formed.

Subsequently, a semiconductor layer is formed over the base insulating film. The semiconductor layer is formed by the following method: a semiconductor film having an amorphous structure is formed by a known method (such as a sputtering method, an LPCVD method, or a plasma CVD method), and is crystallized by a known crystallization method (such as a laser crystallization method, a thermal crystallization method, or a thermal crystallization method using a catalyst such as nickel) to obtain a crystalline semiconductor film. The crystalline semiconductor film is patterned into a desired shape using a first photomask to obtain the semiconductor layer. The semiconductor layer is formed to have a thickness of 25 to 80 nm (preferably 30 to 70 nm thick). There is no particular limitation on the material of the crystalline semiconductor film; however, silicon, silicon germanium (SiGe) alloy or the like may be preferably used.

In addition, a continuous wave laser may be used for crystallization treatment of the semiconductor film having an amorphous structure. When the amorphous semiconductor film is crystallized, it is preferable that second to fourth harmonics of a fundamental wave be applied by using a solid laser that can oscillate continuously to obtain a crystal with a large grain size. Typically, a second harmonic (532 nm) or a third harmonic (355 nm) of an Nd:YVO₄ laser (a fundamental wave, 1064 nm) may be applied. When a continuous wave laser is used, laser light emitted from a continuous wave YVO₄ laser of output of 10 W is converted to harmonic by a nonlinear optical element. There is also a method for emitting a harmonic by putting a YVO₄ crystal and a nonlinear optical element in a resonator. Then, the harmonic is preferably formed so as to have a rectangular or elliptical shape on an irradiated surface by an optical system and emitted onto an object to be processed. At this time, an energy density of about 0.01 to 100 MW/cm² (preferably 0.1 to 10 MW/cm²) is required. The semiconductor film may be irradiated by being moved relatively to the laser light at speeds of about 10 to 2000 cm/s.

In addition, laser crystallization may be performed using pulsed laser light with a repetition rate of 0.5 MHz or more and using a frequency band that is much higher than a generally used frequency band of several tens to several hundreds Hz. It is said that the time required for the semiconductor film irradiated with pulsed laser light to be melted and then solidified completely is several tens nsec to several hundreds nsec. By using the above frequency band, the semiconductor film can be irradiated with pulsed laser light after being melted by the previous laser light and before being solidified. Accordingly, the interface between the solid phase and the liquid phase can be moved continuously in the semiconductor film; therefore, a semiconductor film having crystal grains grown continuously in the scanning direction is formed. Specifically, a cluster of crystal grains of which width in a scanning direction is 10 to 30 μm and width in a direction perpendicular to the scanning direction is approximately 1 to 5 μm can be formed. By forming crystal grains of a single crystal that extends long along the scanning direction, a semiconductor film can be formed, in which crystal grain boundaries hardly exist at least in a channel direction of a thin film transistor.

Crystallization of the amorphous semiconductor film may be performed by a combination of heat treatment and laser light irradiation, or by independently performing heat treatment or laser light irradiation plural times.

After removing a resist mask, a gate insulating film 1003 covering the semiconductor layer is formed. The gate insulating film 1003 is formed by a plasma CVD method or a sputtering method to have a thickness of 1 to 200 nm.

Next, a conductive film with a thickness of 100 to 600 nm is formed over the gate insulating film 1003. Here, a conductive film made of a stacked-layer of a TaN film and a W film is formed by a sputtering method. Although an example of the conductive film made of a stacked-layer of a TaN film and a W film is shown here, the conductive film is not particularly limited. The conductive film may be formed of a single layer of an element selected from Ta, W, Ti, Mo, Al, or Cu, or an alloy material or a compound material containing the element as its main component; or a stacked layer thereof. Further, a semiconductor film typified by a polycrystalline silicon film doped with an impurity element such as phosphorus may be used.

Subsequently, a resist mask is formed using a second photomask to perform etching with the use of a dry etching method or a wet etching method. The conductive film is etched by this etching step to obtain conductive layers 1004 to 1008. It is to be noted that these conductive layers become a gate electrode of TFTs.

After removing the resist mask, a resist mask is newly formed using a third photomask, and in order to form an n-channel TFT of a driver circuit, a first doping step is performed for doping the semiconductor with an impurity element imparting n-type conductivity (typically, phosphorus or As) at low concentration. The resist mask covers a region to be a p-channel TFT and a vicinity of the conductive layer. Doping is performed through the gate insulating film 1003 by this first doping step to form low concentration-impurity regions 1009 and 1010. One light-emitting element is driven with the use of a plurality of TFTs. However, in a case where the light-emitting element is driven by only p-channel TFTs or in a case where a pixel and a driver circuit are not formed over the same substrate, the above doping step is not particularly needed.

Then, after removing the resist mask, a resist mask is newly formed using a fourth photomask, and a second doping step is performed for doping the semiconductor with an impurity element imparting p-type conductivity (typically boron) at high concentration. Doping is performed through the gate insulating film 1003 by this second doping step to form p-type high concentration-impurity regions 1011 to 1017.

Subsequently, a resist mask is newly formed using a fifth photomask, and in order to form an n-channel TFT of the driver circuit, a third doping step is performed for doping the semiconductor with an impurity element imparting n-type conductivity (typically, phosphorus or As) at high concentration. The third doping step is performed on a condition that the dose amount is 1×10¹³ to 5×10¹⁵/cm², and an accelerating voltage is 60 to 100 keV. The resist mask covers a region to be a p-channel TFT region and a vicinity of the conductive layer. Doping is performed through the gate insulating film 1003 by this third doping step to form n-type high concentration impurity regions 1018 and 1019.

Thereafter, the resist mask is removed. Then, after forming a first interlayer insulating film 1020 including hydrogen, the impurity element added to the semiconductor layer is activated and hydrogenated. As for the first interlayer insulating film 1020 including hydrogen, a silicon nitride oxide film (a SiNO film) that is obtained by a PCVD method is used. In addition, in a case where the semiconductor layer is crystallized with the use of a metal element promoting crystallization, typically, nickel, gettering for reducing nickel in a channel formation region can be performed concurrently with the activation.

Next, a second interlayer insulating film 1021 for planarization is formed. As for the second interlayer insulating film 1021, an insulating film in which a skeleton structure is formed by a bond of silicon (Si) and oxygen (O), which is obtained by a coating method, is used. Alternatively, as for the second interlayer insulating film 1021, an organic resin film having a light-transmitting property can be used.

Subsequently, etching is performed using a sixth mask, and a contact hole is formed in the second interlayer insulating film 1021 concurrently with removing the second interlayer insulating film 1021 in a peripheral portion 1042.

Then, etching is performed using the sixth mask continuously as a mask to selectively remove the gate insulating film 1003 and the first interlayer insulating film 1020, which are exposed.

After removing the sixth mask, a conductive film having a three-layer structure, which is in contact with the semiconductor layer in the contact hole, is formed. It is preferable that these three layers be continuously formed by the same sputtering device so as not to oxidize a surface of each layer. However, the conductive film is not limited to the three-layer structure. The conductive film may have two layers or a single layer, and as a material thereof, an element selected from Ta, W, Ti, Mo, Al, or Cu, or an alloy material or a compound material including the element as its main component may be used.

Then, etching of the conductive film is performed using a seventh mask to form a wiring or an electrode. As the wiring or electrode, a connection electrode 1022 that connects a first electrode and a TFT is shown in a pixel portion 1040, and a connection electrode 1023 that electrically connects an n-channel TFT and a p-channel TFT is shown in a driver circuit portion 1041.

Next, a transparent conductive film is formed to be in contact with the wiring or electrode having the above three-layer structure. Then, etching of the transparent conductive film is performed using an eighth mask to form first electrodes 1024R, 1024C, and 1024B, in other words, an anode (or a cathode) of an organic light-emitting element and an inorganic light-emitting element each.

As a material of the first electrode, ITO (indium tin oxide) or ITSO (indium tin oxide containing silicon oxide, obtained by sputtering using a target of ITO which contains silicon oxide at 2 to 10 wt %) is used. In addition to ITSO, a transparent conductive film such as an oxide conductive film having a light-transmitting property (IZO) including silicon oxide, in which zinc oxide (ZnO) of 2 to 20% is mixed into indium oxide, may be used. A transparent conductive film of ATO (antimony tin oxide) may also be used.

In a case where ITO is used for the first electrodes 1024R, 1024Q and 1024B, baking for crystallization is performed to lower electric resistivity. On the other hand, ITSO and IZO are not crystallized as ITO when performing baking, and they keep an amorphous state.

Next, an insulator 1025 (referred to as a bank, a partition, a barrier, an embankment, or the like) covering an edge of the first electrodes 1024R, 1024G, and 1024B is selectively formed using the eighth mask. As the insulator 1025, a tantalum oxide film or a titanium oxide (TiO₂) film obtained by a sputtering method, or an organic resin film obtained by a coating method, with a thickness in a range of 0.8 to 1 μm, is used.

Subsequently, an inorganic material layer 1026 that is to be a light-emitting layer of an inorganic EL element is selectively formed by a screen printing method. Here, after spherical particles of ZnS:Tm (with an average particle diameter of 1 μm) are manufactured, the particles are dispersed in an acrylic resin solution. Thereafter, the inorganic material layer is selectively formed over the first electrodes 1024G and 1024B using the dispersion liquid by a screen printing method and baked. A thickness of the inorganic material layer 1026 is about 8 μm here, and the inorganic material layer is used as a common light-emitting layer for a green pixel and a blue pixel.

Next, an insulating layer 1027 is formed over the inorganic material layer 1026. The insulating layer 1027 is formed by a sputtering method or an EB evaporation method. As a material of the insulating layer 1027, silicon oxide (SiOₓ), silicon nitride (SiNₓ), silicon including oxygen and nitride, aluminum nitride (AlN), aluminum including oxygen and nitrogen or aluminum oxide (Al₂O₃), titanium oxide (TiO₂), barium titanate (BaTiO₃), strontium titanate (SrTiO₃), lead titanate (PbTiO₃), potassium niobate (KNbO₃), lead niobate (PbNbO₃), tantalum oxide (Ta₂O₅), barium tantalate (BaTa₂O₆), lithium tantalate (LiTaO₃), yttrium oxide (Y₂O₃), or the like can be used. Here, after tantalum oxide (Ta₂O₅) is formed by a sputtering method using a tantalum target in an oxygen atmosphere, a mask is formed to selectively perform etching using hydrofluoric acid at high concentration (for example, 49% HF). It is to be noted that the tantalum oxide film has a thickness of 0.3 μm.

Subsequently, an organic material layer 1028 that is to be a light-emitting layer of an organic light-emitting element is formed over the first electrode 1024R by an evaporation method. In order to improve reliability of the organic light-emitting element, vacuum heating and degassing are preferably performed before forming the organic material layer 1028. For example, before an organic compound material is evaporated, heating treatment at 200 to 300° C. is desirably performed in a reduced-pressure atmosphere or an inert atmosphere in order to remove a gas included in the substrate. Further, reliability of the inorganic light-emitting element is improved by this degassing. Here, as the organic material layer 1028 of the light-emitting element emitting red light, a material including a triplet compound is used. As the organic material layer 1028, a 2,3,7,8,12,13,17,18-octaethyl-21H,23H-porphyrin-platinum complex (hereinafter abbreviated as PtOEP) that is a red phosphorescent material is used as dopant for a host material and formed by a co-evaporation method. The organic material layer is not limited to the red phosphorescent material, and another triplet compound shown in Embodiment Mode 1 can be used. Since evaporation is selectively performed with the use of an evaporation mask, the vaporized triplet compound is scattered to the upper side and deposited in a desired portion of the substrate through an opening provided in the metal mask.

Then, a second electrode 1029 is formed over an entire surface of the pixel portion. Here, as the second electrode 1029, an ITO film that is a transparent conductive film formed to have a thickness of 0.4 μm by a sputtering method is used. As a material of the second electrode 1029, MgAg, Mgln, AlLi, or the like can be used. It is to be noted that the second electrode 1029 may not be necessary to be a common electrode for the inorganic light-emitting element and the organic light-emitting element, and may be selectively formed. Further, before forming the second electrode 1029, a layer having a light-transmitting property made from CaF₂, MgF₂, or BaF₂ (with a thickness of 1 to 5 nm) may be selectively formed as a cathode buffer layer over the first electrode 1024R.

Subsequently, a sealing material 1031 is used for sealing. As a material of the sealing material 1031, a metal material, a ceramic material, a glass substrate, or the like can be used. The sealing material 1031 is attached with a sealant 1032 to the peripheral portion 1042 of the substrate 1001. A spacer material or filler may be used for keeping an interval between the substrates uniformity. A space 1030 between a pair of substrates is preferably filled with an inert gas.

In order to achieve full-color display, a transparent base material 1033 provided with color layers (a green color layer 1034G and a blue color layer 1034B) and a black layer (black matrix) 1035 is aligned to be fixed to the substrate 1001. The color layers and the black layer are covered with an overcoat layer 1036.

When a voltage is applied between the pair of electrodes of the thus obtained organic light-emitting element, a red light-emitting region 1044R can be obtained. When a voltage is applied between the pair of electrodes of the inorganic light-emitting element that is combined with the color layer, a blue light-emitting region 1044B and a green light-emitting region 1044G can be obtained. By these combinations, full-color display with high luminance and a favorable color reproduction property can be obtained.

In this embodiment mode, an example is shown, in which the inorganic light-emitting element is a dispersed inorganic EL and an insulating layer is provided over the light-emitting layer so as to be contacted with the light-emitting layer. However, a structure of the present invention is not particularly limited thereto, and any stacked-layer structures of FIGS. 2A to 2C and FIGS. 3A to 3C may be employed.

Thorough the above steps, an active light-emitting display device having a structure shown in FIG. 9 becomes a thin-type full-color display device with the long lifetime, in which desired luminance and desired color purity can be obtained at a low voltage.

In this embodiment mode, a TFT connected to the inorganic light-emitting element has a double gate structure so as to attempt improvement in dielectric strength voltage, which has a different structure from that of a TFT connected to the organic light-emitting element. In such a manner, the TFT connected to the inorganic light-emitting element and the TFT connected to the organic light-emitting element are separately formed, whereby each TFT can have an optimal structure that is adapted for an electric characteristic of each light-emitting element.

Here, a top gate TFT having polysilicon as an active layer is used. However, a TFT of the present invention is not particularly limited as long as it can serve as a switching element, and a bottom gate (inverted staggered) TFT or a staggered TFT can be used. Further, a TFT having an amorphous silicon film or a ZnO film as an active layer may be used. The present invention is not limited to a TFT having a single gate structure or a double gate structure, and a multi-gate TFT having three or more channel formation regions may be employed.

Further, an example in which full-color display is performed by three-color driving of RGB is shown here; however, the present invention is not particularly limited thereto, and full-color display by four-color driving of RGBW may be performed.

This embodiment mode can be freely combined with any one of Embodiment Modes 1 to 7.

### EMBODIMENT MODE 9

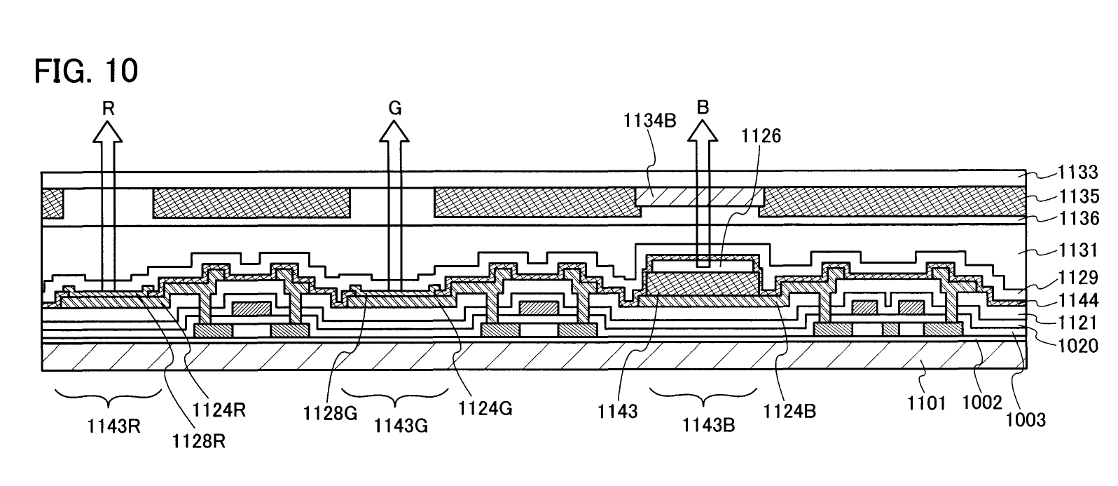

Here, a manufacturing example of an active light emitting display device that is different from that in Embodiment Mode 8 will be described with reference to FIG. 10. FIG. 10 shows a cross-sectional view of a pixel portion. In Embodiment Mode 8, an example is shown, in which light emission is extracted from the substrate side set as a display surface. However, in this embodiment mode, an example is shown, in which light emission is extracted from a surface opposite to a substrate 1101 side set as a display surface. In addition, in Embodiment Mode 8, an example in which the green pixel and the blue pixel are each inorganic EL element is shown. However, in this embodiment mode, an example in which only a blue pixel is an inorganic EL element is shown.

An inorganic EL element of this embodiment mode has a structure in which a light-emitting layer is surrounded by an insulating layer as shown in FIG. 2C or FIG. 3C, which is different from that in Embodiment Mode 8.

A structure of the inorganic EL element of this embodiment mode is almost the same as that of Embodiment Mode 8 except for part of the structure. Therefore, the same reference numeral is used for the same portion, and the repeated explanation is briefly described.

Light emission may be extracted from the surface opposite to a substrate 1101 side set as a display surface. In that case, as for the substrate 1101, a silicon substrate, a ceramic substrate, a metal substrate, or a stainless substrate having a surface over which an insulating film is formed as well as a glass substrate and a quartz substrate may be used. Here, a ceramic substrate that can resist high temperature treatment is used for the substrate 1101.

First, a base insulating film 1002 for planarization is formed over the substrate 1101. As the base insulating film 1002, a base film made of an insulating film such as a silicon oxide film, a silicon nitride film, or a silicon oxynitride film is formed.

The subsequent steps are performed as similar to those of Embodiment Mode 8 as follows: a semiconductor layer is formed over the base insulating film 1002; a gate insulating film 1003 covering the semiconductor layer is formed; a gate electrode is formed over the gate insulating film; doping treatment is appropriately performed; a first interlayer insulating film 1020 including hydrogen is formed; and an impurity element added to the semiconductor layer is activated and hydrogenated.

Next, a second interlayer insulating film 1121 is formed using an inorganic insulating material with high heat resistance over the first interlayer insulating film 1020. As the second interlayer insulating film 1121, an insulating film such as a silicon oxide film, a silicon nitride film, or a silicon oxynitride film is used. Further, aluminum nitride (AlN), aluminum including oxygen and nitrogen or aluminum oxide (Al₂O₃), titanium oxide (TiO₂), barium titanate (BaTiO₃), strontium titanate (SrTiO₃), lead titanate (PbTiO₃), potassium niobate (KNbO₃), lead niobate (PbNbO₃), tantalum oxide (Ta₂O₅), barium tantalate (BaTa₂O₆), lithium tantalate (LiTaO₃), yttrium oxide (Y₂O₃), or the like is used.

Subsequently, a contact hole that reaches the semiconductor layer is formed by selective etching as similar to Embodiment Mode 8.

Next, a conductive film that is in contact with the semiconductor layer in the contact hole is formed. As the conductive film, a conductive film made of a TiN film is formed by a sputtering method. The conductive film is a TiN film here; however, it is not particularly limited. The conductive film may be formed of a single layer of an element selected from Ta, W, Ti, Mo, Al, or Cu, or an alloy material or a compound material containing the element as its main component; or a stacked layer thereof. Further, a semiconductor film typified by a polycrystalline silicon film doped with an impurity element such as phosphorus may be used. Here, a conductive film having high heat resistance that is in contact with the semiconductor layer is preferably made.

Then, etching of the conductive film is performed to form first electrodes 1124R, 1124G, and 1124B, in other words, an anode (or a cathode) of an organic light-emitting element and an inorganic light-emitting element each.

Subsequently, a thick insulating layer 1143 with a thickness of 10 μm to 50 μm is selectively formed over the first electrode 1124B by a printing and baking method or a sol-gel method. As a material of the thick insulating layer 1143, lead titanate, lead niobate, barium titanate, or the like is used. In a case of forming the thick insulating layer 1143 by a printing and baking method, a grain size of the material is uniformed and mixed with a binder to make a paste having appropriate viscosity. After the paste is selectively applied by a screen printing method, the paste is dried. Then, the paste is baked at the appropriate temperature. A TFT manufacturing step that can resist this baking temperature is preferably performed.

Next, an inorganic material layer 1126 is formed by a screen printing method or an electron beam evaporation method. As a material of the inorganic material layer 1126, BaAl₂S₄: Eu is used.

Next, a thin insulating layer 1144 is formed. The thin insulating layer 1144 is formed by a sputtering method, an evaporation method, a CVD method, a sol-gel method, or a printing and baking method. As the thin insulating layer 1144, barium tantalate, silicon oxide, silicon nitride, tantalum oxide, barium titanate, or the like can be used.

Subsequently, the thin insulating layer 1144 is selectively etched to expose part of the first electrodes 1124R and 1124C. Here, after tantalum oxide (Ta₂O₅) is formed by a sputtering method using a tantalum target in an oxygen atmosphere, a mask is formed, and etching is selectively performed using a mixture gas including BCl₃, Cl₂, and N₂.

Then, an organic material layer 1128R that is to be a light-emitting layer of an organic light-emitting element is formed over the first electrode 1124R by an evaporation method, and an organic material layer 1128G that is to be a light-emitting layer of an organic light-emitting element is formed over the first electrode 1124G by an evaporation method. In the organic material layer 1128R, a red phosphorescent material is used as an evaporation material, and in the organic material layer 1128Q a green phosphorescent material is used as an evaporation source. It is to be noted that the triplet compound shown in Embodiment Modes 1 to 3 can be used for the materials of the organic material layer 1128R and the organic material layer 1128G.

In addition, the thin insulating layer 1144 also serves as a partition layer between a red light-emitting region 1143R and a green light-emitting region 1143G; therefore short-circuit between the light-emitting elements can be prevented.

Next, a second electrode 1129 is formed over an entire surface of the pixel portion. Here, as the second electrode 1129, an ATO film that is a transparent conductive film is formed to have a thickness of 100 nm by a sputtering method.

In order to perform sealing, a light-transmitting base 1133 is used. Attachment of the light-transmitting base 1133 is performed with a transparent adhesive 1131. In order to achieve full-color display, the light-transmitting base 1133 provided with a color layer (a blue color layer 1134B) and the black layer 1135 is aligned with and attached to the substrate 1101. It is to be noted that the color layer and the black layer are covered with an overcoat layer 1136.

When a voltage is applied between a pair of electrodes of the thus obtained organic light-emitting element, the red light-emitting region 1143R and the green light-emitting region 1143G can be obtained. In addition, when a voltage is applied between a pair of electrodes of an inorganic light-emitting element that is combined with the color layer, a blue light-emitting region 1143B can be obtained. By these combinations, full-color display with high luminance and a favorable color reproduction property can be obtained.

In this embodiment mode, an example in which the inorganic light-emitting element is a thin-film inorganic EL and the insulating layer is provided to surround the light-emitting layer is shown; however, the present invention is not particularly limited thereto. Any stacked-layer structures of FIGS. 2A to 2C and FIGS. 3A to 3C may be employed.

Through the above steps, the active light-emitting display device having a structure shown in FIG. 10 becomes a thin-type full-color display device with the long lifetime, in which desired emission luminance and desired color purity can be obtained at a low voltage.

Here, an example in which full-color display is performed by three-color driving of RGB is shown; however, the present invention is not particularly limited thereto. Full-color display device may be performed by four-color driving of RGBW.

This embodiment mode can be freely combined with any one of Embodiment Modes 1 to 8.

### EMBODIMENT MODE 10

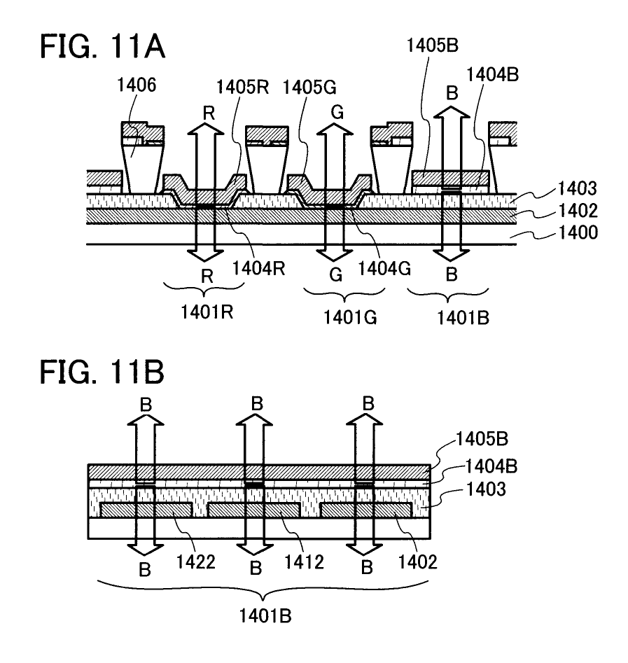

In this embodiment mode, a manufacturing example of a passive display device in a case where stacked-layer structures of an inorganic EL element and an organic EL element are different from each other will be described with reference to FIGS. 11A and 11B.

The example shown in FIG. 4 shows an optimal combination of an inorganic EL element and an organic EL element, in which the inorganic EL element has a stacked-layer structure shown in FIG. 2A or FIG. 3A in a case where the inorganic EL element and the organic EL element are formed over the same substrate. In other words, after the first electrode and the partition layer are formed, the light-emitting layer of the inorganic EL element is selectively formed by an evaporation method or a coating method. Thereafter, the light-emitting layer of the organic EL element is selectively formed by an evaporation method, and then the second electrode may be formed.

In a case where the inorganic EL element has a stacked-layer structure shown in FIG. 2B, FIG. 2C, FIG. 3B, or FIG. 3C, the insulating layer is provided between the first electrode and the second electrode; therefore, a step is needed separately from a manufacturing step of the organic EL element.

Thus, in this embodiment mode, the same material is used for a partition layer provided between a first organic EL element of a color and a second organic EL element of a color and an insulating layer provided between a pair of electrodes of a third inorganic EL element of a color, whereby the step is simplified.

First, first stripe-shaped wirings 1402, 1412, and 1422 that extend in parallel to a first direction are formed over a substrate 1400. FIG. 11A is a cross-sectional view at a surface including a line in parallel to the first wiring 1402 that extends in parallel to the first direction. FIG. 11B is a cross-sectional view cut along a second direction perpendicular to the first direction. In FIG. 11B, a wiring that is next row to the first wiring 1402 is a wiring 1412, and the wiring that is next row to the wiring 1412 is a wiring 1422.

Next, an insulating layer 1403 covering the first stripe-shaped wirings 1402, 1412, and 1422 is formed. As the insulating layer 1403, silicon oxide (SiOₓ), silicone nitride (SiNₓ), silicon including oxygen and nitrogen, aluminum nitride (AlN), aluminum including oxygen and nitrogen or aluminum oxide (Al₂O₃), titanium oxide (TiO₂), barium titanate (BaTiO₃), strontium tiatante (SrTiO₃), lead titanate (PbTiO₃), potassium niobate (KNbO₃), lead niobate (PbNbO₃), tantalum oxide (Ta₂O₅), barium tantalate (BaTa₂O₆), lithium tantalate (LiTaO₃), yttrium oxide (Y₂O₃), or the like can be used. It is to be noted that this insulating layer 1403 also serves as an insulating layer that is arranged below an inorganic material layer 1404B of the inorganic light-emitting element; therefore, a thickness of the insulating layer 1403 is preferably adjusted.

Subsequently, an opening is formed by selective etching of the insulating layer 1403 to expose a top surface of a first electrode where a red light-emitting region 1401R and a green light-emitting region 1401G are to be formed. Although not shown here, an opening is formed on an end of the first electrode so that an FPC (Flexible Printed Circuit) can be connected thereto.

Next, a partition layer 1406 is formed over the insulating layer 1403. A side wall of the partition layer 1406 has such a gradient that the distance between one side wall and the other side wall becomes narrower toward the substrate surface.

Subsequently, the inorganic material layer 1404B of the inorganic light-emitting element is selectively formed in a region to be formed a blue light-emitting region 1401B by an electron beam evaporation method. Then, organic material layers 1404R and 1404G of the organic light-emitting element are selectively formed by a resistance heating method. The organic material layer 1404R includes a red phosphorescent material, and the organic material layer 1404G includes a green phosphorescent material.

The inorganic material layer 1404B and the organic material layers 1404R and 1404G are evaporated over the partition layer 1406. However, a distance from the first electrode is held because the side wall of the partition layer 1406 has such a gradient that the distance between one side wall and the other side wall becomes narrower toward the substrate surface.

Then, a conductive film is formed by an evaporation method or a sputtering method, whereby second electrodes 1405R, 1405Q and 1405B extending in the second direction that is perpendicular to the first direction are formed. It is to be noted that the conductive film is formed over the partition layer 1406; however, a distance from the first electrode is held by the partition layer 1406, and then the conductive film over the partition layer does not serve as a wiring.

Through the above steps, a passive light-emitting display device having a structure shown in FIGS. 11A and 11B becomes a thin-type full-color display device with the long lifetime, in which desired emission luminance and desired color purity can be obtained at a low voltage. It is to be noted that the structure of the inorganic light-emitting element of this embodiment mode corresponds to the stacked-layer structure of FIG. 2B.

This embodiment mode can be freely combined with any one of Embodiment Modes 1 to 7.

The present invention having the above structure will be explained in more detail in embodiments below.

### EMBODIMENT 1

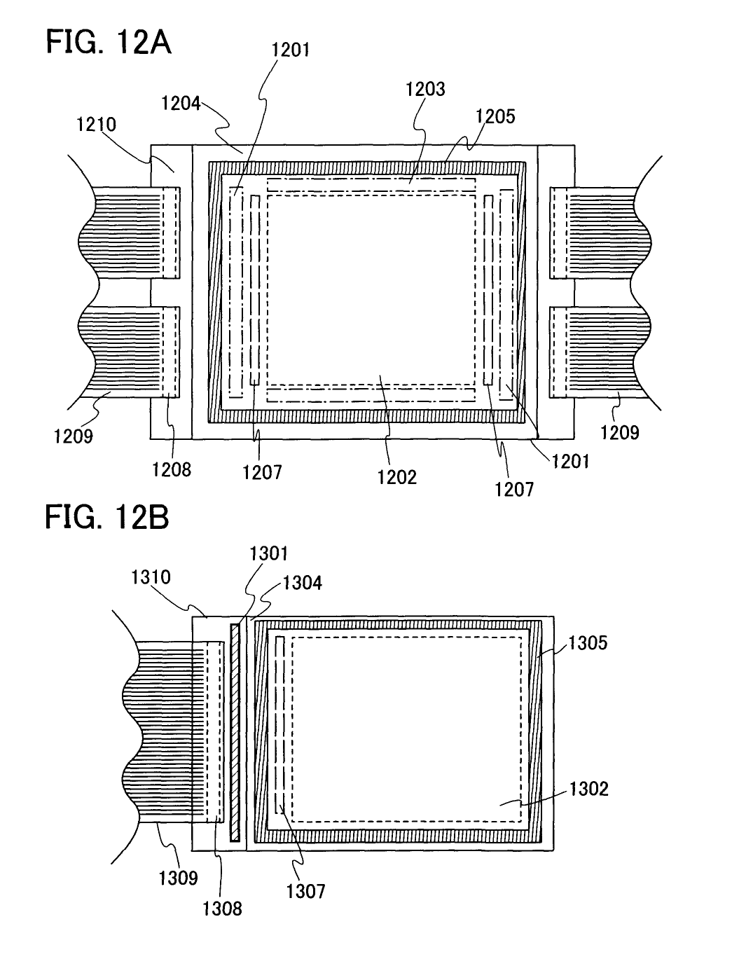

In this embodiment, an example in which an FPC or a driving IC (Integrated Circuit) for driving is mounted on a full-color light-emitting display panel will be explained with reference to FIGS. 12A and 12B. In the full-color light-emitting display panel, the three-color driving of RGB described in any one of Embodiment Modes 1 to 7 may be employed. In a plurality of light-emitting elements emitting different colors (for example, colors of R, G and B), at least one of the light-emitting elements of an emission color is a light-emitting element including an organic compound (organic EL element), and another light-emitting element of an emission color is a light-emitting element using an inorganic material as a light-emitting layer or a fluorescent layer (inorganic EL element).

A view of FIG. 12A shows an example of a top view of a light emitting device in which FPCs 1209 are attached to four places of a terminal portion 1208. A pixel portion 1202 including a light-emitting element and a TFT, a gate driver circuit 1203 including a TFT, and a source driver circuit 1201 including a TFT are formed over a substrate 1210. These circuits are formed over the same substrate, in each of which an active layer of the TFT is formed using a semiconductor film having a crystalline structure. Accordingly, a full-color display panel in which a system-on-panel is achieved can be manufactured.

In a case where a panel by four-color driving of RGBW that can improve luminance is used instead of the panel by three-color driving of RGB, a driver circuit is needed for converting a three-color video signal into a four-color video signal. Therefore, when the driver circuit is formed using a TFT, the number of components can be reduced.

Connection regions 1207 that are provided in two places so as to sandwich the pixel portion are provided so that a second electrode of the light-emitting element is contacted with a wiring of the lower layer. A first electrode of the light-emitting element is electrically connected to the TFT provided in the pixel portion.

A sealing substrate 1204 is fixed to the substrate 1210 with the use of a sealant 1205 surrounding the pixel portion and the driver circuit and a filling material surrounded by the sealant. Further, a filling material including a transparent drying agent may fill the space. A drying agent may be arranged in a region that is not overlapped with the pixel portion.

The structure shown in FIG. 12A is an example that is suitable for a light emitting device having a relatively large size of a XGA-class (e.g., a diagonal of 4,3-inch). FIG. 12B is an example employing a COG (Chip On Glass) method that is suitable for a compact size with a narrower frame (e.g., a diagonal of 1,5-inch).

In FIG. 12B, a driver IC 1301 is mounted over a substrate 1310, and an FPC 1309 is mounted over a terminal portion 1308 that is arranged beyond the driver IC 1301. From an aspect of increasing productivity, a plurality of driver ICs 1301 are preferably formed over a rectangle substrate that is 300 to 1000 mm or more on one side. In other words, a plurality of circuit patterns, each of which has a driver circuit portion and an input/output terminal as one unit, is formed over the substrate and divided so that the driver ICs can be obtained separately. As for the length of the driver IC, the driver IC may be formed to have a rectangular shape having a longer side of 15 to 80 mm and a shorter side of 1 to 6 mm, considering length of one side of the pixel portion or pixel pitch, or may be formed so that the length of the longer side is a length corresponding to one side of a pixel region or a length obtained by adding one side of each driver circuit and one side of the pixel portion to each other.

For the outside dimension, the driver IC has an advantage over an IC chip in the length of the longer side. When a driver IC formed to have a longer side of 15 to 80 mm is used, the number of driver ICs to be required for mounting corresponding to the pixel portion is smaller than the case of using an IC chip, whereby the yield in manufacturing can be improved. In addition, when a driver IC is formed over a glass substrate, the productivity is not decreased because the driver IC is not limited to the shape of a host substrate. This is a great advantage as compared with a case of taking out IC chips from a circular silicon wafer.

In addition, a TAB (Tape Automated Bonding) method may also be employed. In that case, a plurality of tapes may be attached and driver ICs may be mounted on the tapes. As in the case of the COG method, a single driver IC may be mounted on a single tape. In this case, a metal piece or the like for fixing the driver IC may be attached together for enhancing strength.

A connection region 1307 provided between a pixel portion 1302 and the driver IC 1301 is provided so that a second electrode of a light-emitting element is in contact with a wiring of a lower layer. A first electrode of the light-emitting element is electrically connected to the TFT provided in the pixel portion 1302.

In addition, a sealing substrate 1304 is fixed to the substrate 1310 with a sealant 1305 surrounding the pixel portion 1302 and a filler material surrounded by the sealant 1305.

In a case where an amorphous semiconductor film is used as an active layer of the TFT in the pixel portion, it is difficult to form the driver circuit over the same substrate, thus the structure of FIG. 12B is employed even for a large size.

As described above, various electronic devices can be completed with the use of the manufacturing method or the structure implementing the present invention, that is, the manufacturing method or the structure in any one of Embodiment Modes 1 to 10.

### EMBODIMENT 2

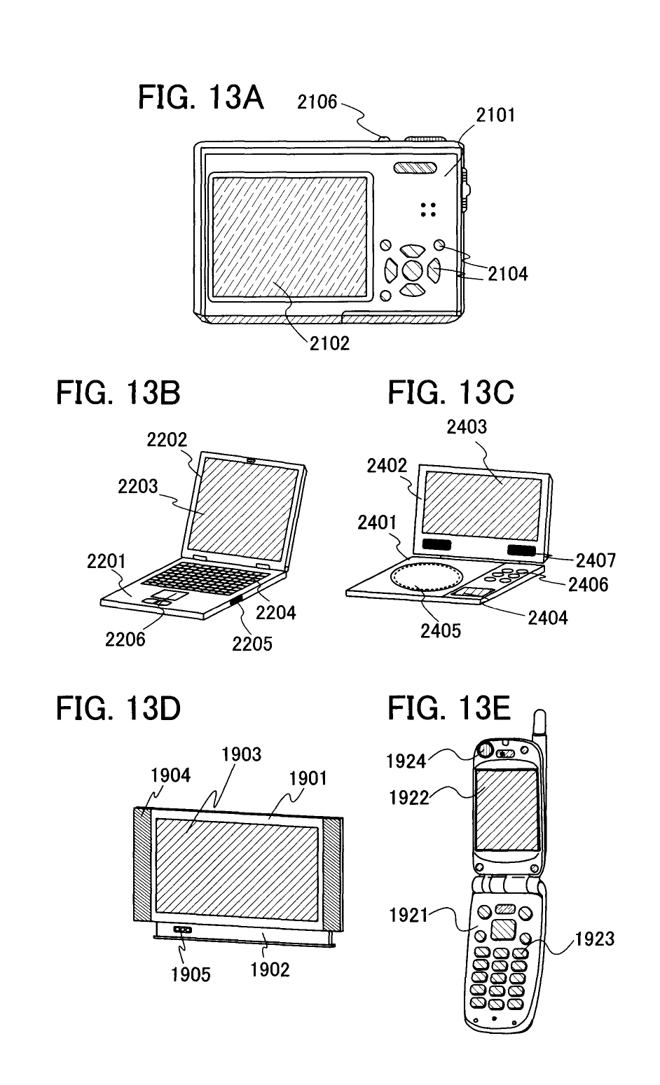

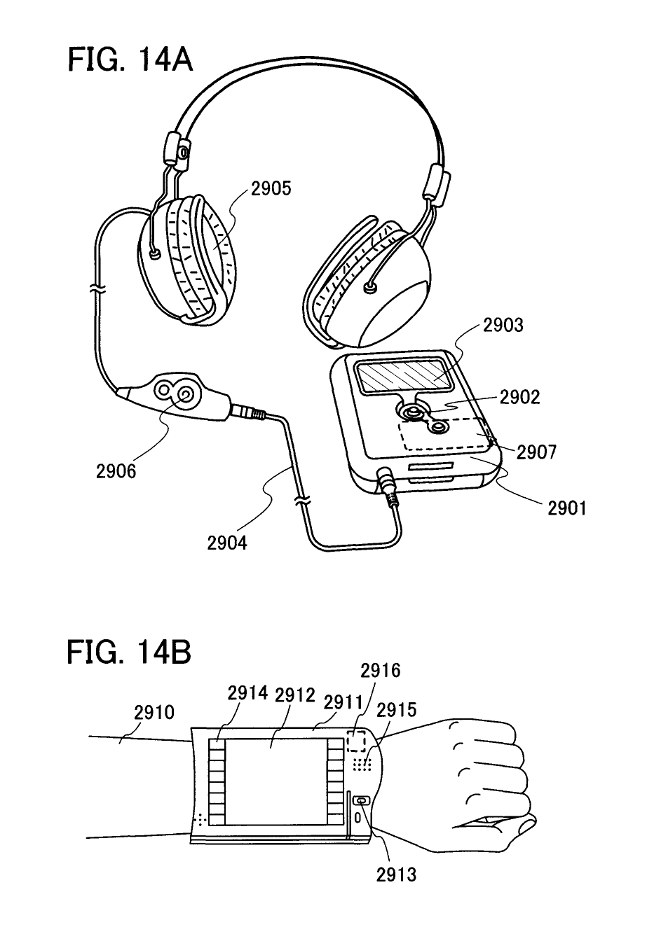

As a semiconductor device and an electronic device of the present invention, there are a camera such as a video camera and a digital camera, a goggle type display (a head mount display), a navigation system, an audio reproducing device (e.g., a car stereo or an audio component system), a personal computer, a game machine, a mobile information terminal (e.g., a mobile computer, a mobile phone, a mobile game machine, or an electronic book), an image reproducing device provided with a recording medium (specifically, a device for reproducing a recording medium such as Digital Versatile Disc (DVD) and provided with a display for displaying the image), and the like. Specific examples of those electronic devices are shown in FIGS. 13A to 13E and FIGS. 14A and 14B.

FIG. 13A shows a digital camera, which includes a main body 2101, a display portion 2102, an imaging portion, operation keys 2104, a shutter 2106, and the like. FIG. 13A is a view from the display portion 2102 side and the imaging portion is not shown. By applying the present invention to the display portion 2102, a digital camera that performs full-color display with a favorable color reproducing property can be achieved.

FIG. 13B shows a personal computer, which includes a main body 2201, a chassis 2202, a display portion 2203, a keyboard 2204, an external connecting port 2205, a pointing mouse 2206, and the like. By the present invention, a personal computer with a favorable color reproducing property can be achieved.

FIG. 13C shows a mobile image reproducing device provided with a recording medium (specifically a DVD reproducing device), which includes a main body 2401, a chassis 2402, a display portion A 2403, a display portion B 2404, a recording medium (such as a DVD) reading portion 2405, operation keys 2406, a speaker portion 2407, and the like. The display portion A 2403 mainly displays image information and the display portion B 2404 mainly displays character information. The image reproducing device provided with a recording medium also includes a home game machine or the like. By the present invention, an image reproducing device that performs full-color display with a favorable color reproducing property can be achieved.

FIG. 13D shows a display device, which includes a chassis 1901, a supporting base 1902, a display portion 1903, a speaker portion 1904, a video input terminal 1905, and the like. This display device is manufactured using a thin film transistor formed by the manufacturing method shown in another embodiment for the display portion 1903 and a driver circuit. The display device includes, in its category, a liquid crystal display device, a light emitting device, and the like, and specifically, all display devices used for displaying information, for example, for a computer, for TV broadcast reception, or for advertisement display. By the present invention, a display device with a favorable color reproducing property, particularly, a large-sized full-color display device that has a large screen of 22 to 50 inches, can be achieved.

FIG. 13E shows a mobile phone, which is a typical example of a mobile information terminal. This mobile phone includes a chassis 1921, a display portion 1922, a sensor portion 1924, operation keys 1923, and the like. The sensor portion 1924 includes an optical sensor element, and current consumption of the mobile phone can be suppressed by controlling luminance of the display portion 1922 in accordance with illuminance obtained at the sensor portion 1924 or controlling lighting of the operation key 1923 in accordance with the illuminance obtained at the sensor portion 1924. In addition, in the case of a mobile phone having an imaging function such as a CCD, whether or not a person taking a picture looks into an optical finder is detected based on the change in the amount of light received by a sensor of the sensor portion 1924 provided in the vicinity of the optical finder. In the case where a person taking a picture looks into the optical finder, power consumption can be suppressed by turning off the display portion 1922.

An electronic device such as a PDA (Personal Digital Assistant), a digital camera, or a compact game machine as well as the above mobile phone is a mobile information terminal, which has a small display screen. Accordingly, by using the full-color panel shown in any one of Embodiment Modes 1 to 10, the electronic device can be downsized and light-weighted.

Another mode of an electronic device mounting a semiconductor device of the present invention is explained with reference to FIG. 14A. Here, a mobile music reproducing device provided with a recording medium is shown, which includes a main body 2901, a display portion 2903, a recording medium (a card type memory, a compact large capacity memory, or the like) reading portion 2907, operation keys 2902 and 2906, speaker portions 2905 of a headphone connected to a connection cord 2904, and the like. By applying the present invention to the display portion 2903, a music reproducing device that displays full-color can be achieved.

Another mode of an electronic device mounting a semiconductor device of the present invention is explained with reference to FIG. 14B. Here, a mobile computer capable of being attached to an arm is shown, which includes a main body 2911, a display portion 2912, a switch 2913, an operation key 2914, a speaker portion 2915, a semiconductor integrated circuit 2916, and the like. Various input and operation are possible for the display portion 2912 used as a touch panel. Although not shown here, the mobile computer is provided with a chilling facility suppressing rise in temperature of the mobile computer and communication facilities such as an infrared port and a high frequency circuit.

A portion of the mobile computer touching a human arm 2910 is preferably covered with a film such as plastic so as not to generate discomfort. Further, an external form of the main body 2911 may be curved along the human arm 2910. The present invention can achieve full-color display with a favorable color reproducing property, and accordingly, a mobile computer with a high precision display image can be achieved.

This application is based on Japanese Patent Application serial no. 2006-058759 filed in Japan Patent Office on Mar. 3 in 2006, the entire contents of which are hereby incorporated by reference.

What is claimed is:

1. A semiconductor device comprising:
a first light-emitting element for emitting a first color; and
a second light-emitting element for emitting a second color which is different from the first color,
wherein the first light-emitting element comprises an inorganic light-emitting layer or an inorganic fluorescent layer, and
wherein the second light-emitting element comprises an organic light-emitting layer having a first organic compound.

2. The semiconductor device according to claim 1, further comprising a third light-emitting element for emitting a third color which is different from the first and second colors.

3. The semiconductor device according to claim 2, wherein the third light-emitting element comprises an organic light-emitting layer having a second organic compound.

4. The semiconductor device according to claim 2, wherein the third light-emitting element comprises an inorganic light-emitting layer or an inorganic fluorescent layer.

5. The semiconductor device according to claim 1, further comprising:
a third light-emitting element for emitting a third color which is different from the first and second colors; and
a fourth light-emitting element for emitting a fourth color which is different from the first, second and third colors.

6. The semiconductor device according to claim 5, wherein the third light-emitting element comprises an organic light-emitting layer having a second organic compound and the fourth light-emitting element comprises an organic light-emitting layer having a third organic compound.

7. The semiconductor device according to claim 5, wherein the third light-emitting element comprises an inorganic light-emitting layer or an inorganic fluorescent layer and the fourth light-emitting element comprises an organic light-emitting layer having a second organic compound.

8. The semiconductor device according to claim 5, wherein the third light-emitting element comprises an inorganic light-emitting layer or an inorganic fluorescent layer and the fourth light-emitting element comprises an inorganic light-emitting layer or an inorganic fluorescent layer.

9. The semiconductor device according to claim 1, wherein each of the first and second colors is red, green, blue, white, cyan, magenta, umber, orange, or yellow.

10. The semiconductor device according to claim 2, wherein the third color is red, green, blue, white, cyan, magenta, umber, orange, or yellow.

11. The semiconductor device according to claim 5, wherein each of the third and fourth colors is red, green, blue, white, cyan, magenta, umber, orange, or yellow.

12. The semiconductor device according to claim 1, further comprising a color filter in a position through which light emission from at least one of the first and second light-emitting elements passes.

13. The semiconductor device according to claim 1, wherein the first organic compound is a triplet compound or a singlet compound.

14. The semiconductor device according to claim 3, wherein the second organic compound is a triplet compound or a singlet compound.

15. The semiconductor device according to claim 6, wherein each of the second and third organic compounds is a triplet compound or a singlet compound.

16. The semiconductor device according to claim 7, wherein the second organic compound is a triplet compound or a singlet compound.

17. The semiconductor device according to claim 1, wherein the semiconductor device is a passive matrix display device.

18. The semiconductor device according to claim 1, wherein the semiconductor device is an active matrix display device.

19. An electronic device having the semiconductor device according to claim 1, wherein the electronic device is one selected from a group consisting of a display device, a digital camera, and a mobile information terminal.

20. A semiconductor device comprising:
a first light-emitting element comprising an organic light-emitting layer having an organic compound;
a second light-emitting element;
a third light-emitting element wherein the second and third light-emitting elements share a same inorganic light-emitting layer or an inorganic fluorescent layer;
a first color filter adjacent to the second light-emitting element; and
a second color filter adjacent to the third light-emitting element, the second color filter having a different color from the first color filter.

21. The semiconductor device according to claim 20, wherein the organic compound is a triplet compound or a singlet compound.

22. The semiconductor device according to claim 20, wherein the semiconductor device is a passive matrix display device.

23. The semiconductor device according to claim 20, wherein the semiconductor device is an active matrix display device.

24. An electronic device having the semiconductor device according to claim 20, wherein the electronic device is one selected from a group consisting of a display device, a digital camera, and a mobile information terminal.

25. A semiconductor device comprising:
a first light-emitting element comprising an organic light-emitting layer having an organic compound;
a second light-emitting element comprising a first inorganic light-emitting layer or an inorganic fluorescent layer;
a third light-emitting element comprising a second inorganic light emitting layer or an inorganic fluorescent layer for emitting a same color as the first inorganic light-emitting layer or an inorganic fluorescent layer;
a first color filter adjacent to the second light-emitting element;
a second color filter adjacent to the third light-emitting element, the second color filter having a different color from the first color filter.

26. The semiconductor device according to claim 25, wherein the organic compound is a triplet compound or a singlet compound.

27. The semiconductor device according to claim 25, wherein the semiconductor device is a passive matrix display device.

28. The semiconductor device according to claim 25, wherein the semiconductor device is an active matrix display device.

29. An electronic device having the semiconductor device according to claim 25, wherein the electronic device is one selected from a group consisting of a display device, a digital camera, and a mobile information terminal.
